(19) United States
(12) Patent Application Publication
(10) Pub. No.: US 2024/0029949 A1
(43) Pub. Date: Jan. 25, 2024

(54) INSULATING TRANSFORMER

(71) Applicant: ROHM CO., LTD., Kyoto-shi (JP)

(72) Inventor: Bungo TANAKA, Kyoto-shi (JP)

(73) Assignee: ROHM CO., LTD., Kyoto-shi (JP)

(21) Appl. No.: 18/475,265

(22) Filed: Sep. 27, 2023

Related U.S. Application Data
(63) Continuation of application No. PCT/JP2022/015035, filed on Mar. 28, 2022.

(30) Foreign Application Priority Data
Mar. 29, 2021 (JP) 2021-055722

(51) Int. Cl. H01F 27/40; H01F 27/32; H01F 27/29; H01G 4/228; H01F 17/00

(52) U.S. Cl. CPC H01F 27/40; H01F 27/324; H01F 27/29; H01G 4/228; H01F 17/0013; H01L 28/10

(57) ABSTRACT

An insulating transformer includes an insulation layer, a transformer embedded in the insulation layer, and a capacitor. The transformer includes first and second coils. The first coil includes a first signal terminal and a first ground terminal. The second coil is separated from the first coil in a thickness direction of the insulation layer and includes a second signal terminal and a second ground terminal. The capacitor includes first and second capacitor electrodes. The first capacitor electrode is connected to the first ground terminal of the first coil. The second capacitor electrode is located between the first capacitor electrode and the second coil and connected to the second ground terminal of the second coil. The insulating transformer further includes a first insulation film located between the first coil and the first capacitor electrode, and a second insulation film located between the second coil and the second capacitor electrode.

### CROSS-REFERENCE TO RELATED APPLICATIONS

This application is a continuation of International Application No. PCT/JP2022/015035, filed Mar. 28, 2022, which claims priority to JP 2021-055722, filed Mar. 29, 2021, the entire contents of each are incorporated herein by reference.

### BACKGROUND

### 1. Field

The present disclosure relates to an insulating transformer.

### 2. Description of Related Art

An insulation gate driver is an example of a gate driver that applies gate voltage to the gate of a switching element such as a transistor. Japanese Laid-Open Patent Publication No. 2018-78169 describes an example of a semiconductor integrated circuit that serves as an insulation gate driver including a transformer with a primary coil at a primary side and a second coil at a secondary side.

### BRIEF DESCRIPTION OF DRAWINGS

FIG. 1 is a schematic diagram illustrating a gate driver of one embodiment.

FIG. 2 is a plan view illustrating the internal structure of the gate driver.

FIG. 3 is a perspective view illustrating a transformer chip of the gate driver.

FIG. 4 is a plan view of the transformer chip shown in FIG. 3.

FIG. 5 is a schematic cross-sectional view illustrating first coils of the transformer chip shown in FIG. 3.

FIG. 6 is a schematic cross-sectional view illustrating second coils of the transformer chip shown in FIG. 3.

FIG. 7 is a schematic cross-sectional view illustrating first capacitor electrodes of the transformer chip shown in FIG. 3.

FIG. 8 is a schematic cross-sectional view illustrating second capacitor electrode of the transformer chip shown in FIG. 3.

FIG. 9 is a cross-sectional view taken along line 9-9 in FIG. 4 illustrating a state in which a transformer chip is mounted on a low-voltage die pad.

FIG. 10A is a cross-sectional view illustrating a method for forming the first coil and the first capacitor electrode.

FIG. 10B is a cross-sectional view illustrating the method for forming the first coil and the first capacitor electrode.

FIG. 11A is a cross-sectional view illustrating a method for forming the second coil and the second capacitor electrode.

FIG. 11B is a cross-sectional view illustrating the method for forming the second coil and the second capacitor electrode.

FIG. 11C is a cross-sectional view illustrating the method for forming the second coil and the second capacitor electrode.

FIG. 12 is a circuit diagram illustrating the operation of a gate driver in a comparative example.

FIG. 13 is a circuit diagram illustrating the operation of the gate driver in the present embodiment.

FIG. 14 is a schematic cross-sectional view illustrating first capacitor electrodes of a transformer chip in a modified example.

FIG. 15 is a schematic cross-sectional view illustrating a first capacitor electrode of a transformer chip in a modified example.

FIG. 16 is a schematic cross-sectional view illustrating first capacitor electrodes of a transformer chip in a modified example.

FIG. 17 is a schematic cross-sectional view illustrating a first coil, a second coil, a dummy coil, a first capacitor electrode, and a second capacitor electrode of a transformer chip in a modified example.

FIG. 18 is a schematic cross-sectional view illustrating a first coil, a second coil, a dummy coil, a first capacitor electrode, and a second capacitor electrode of a transformer chip in a modified example.

FIG. 19 is a schematic cross-sectional view illustrating a first coil, a second coil, a dummy coil, a first capacitor electrode, and a second capacitor electrode of a transformer chip in a modified example.

FIG. 20 is a schematic cross-sectional view illustrating a first coil, a second coil, a dummy coil, a first capacitor electrode, and a second capacitor electrode of a transformer chip in a modified example.

FIG. 21 is a schematic cross-sectional view illustrating a first coil, a second coil, a dummy coil, a first capacitor electrode, and a second capacitor electrode of a transformer chip in a modified example.

FIG. 22 is a schematic cross-sectional view illustrating a first coil, a second coil, a dummy coil, a first capacitor electrode, and a second capacitor electrode of a transformer chip in a modified example.

FIG. 23 is a schematic cross-sectional view illustrating a first coil, a second coil, a dummy coil, a first capacitor electrode, and a second capacitor electrode of a transformer chip in a modified example.

FIG. 24 is a schematic cross-sectional view illustrating a first coil, a second coil, a dummy coil, a first capacitor electrode, and a second capacitor electrode of a transformer chip in a modified example.

FIG. 25 is a schematic cross-sectional view illustrating a first coil, a second coil, a dummy coil, a first capacitor electrode, and a second capacitor electrode of a transformer chip in a modified example.

### DETAILED DESCRIPTION

An embodiment of a gate driver device will now be described with reference to the drawings.

The embodiments described below exemplify configurations and methods for embodying a technical concept without any intention to limit the material, shape, structure, arrangement, dimensions, and the like of each component. In the accompanying drawings, elements are illustrated for simplicity and clarity and may be exaggerated. Such elements have not necessarily been drawn to scale. To facilitate understanding, hatching lines of certain elements may not be shown in the cross-sectional drawings. Throughout the drawings and the detailed description, the same reference numerals refer to the same elements.

Gate Driver

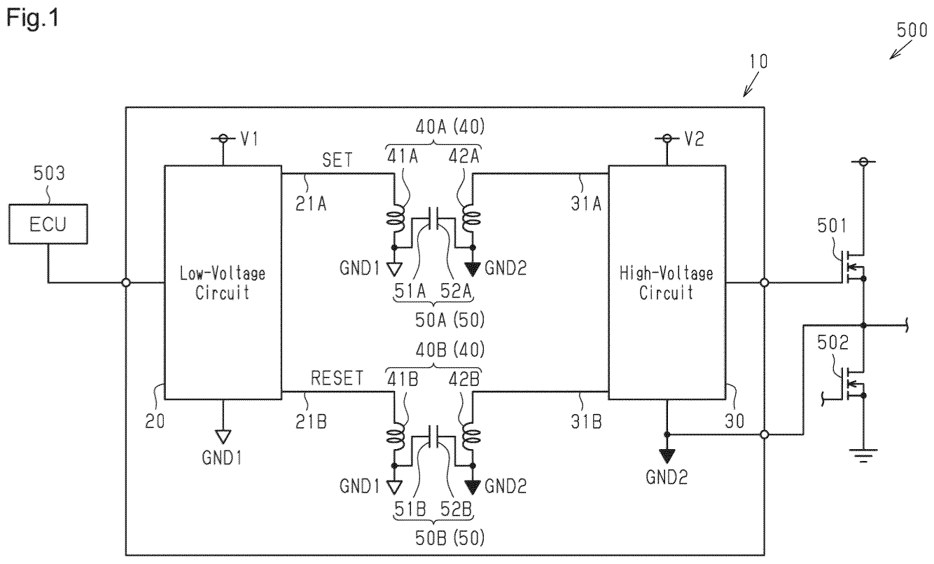

A gate driver 10 according to one embodiment will now be described with reference to FIGS. 1 to 9.

FIG. 1 shows one example of a circuitry configuration of the gate driver 10. The gate driver 10 is configured to apply a drive voltage signal to the gate of a switching element and is used in, for example, an inverter device 500 mounted on an electric vehicle or a hybrid electric vehicle. The inverter device 500 includes two switching elements 501 and 502 connected in series to each other, the gate driver 10, and an electronic control unit (ECU) 503 that controls the gate driver 10. The switching element 501 is, for example, a high-side switching element connected to a drive power supply. The switching element 502 is a low-side switching element. The switching elements 501 and 502 may be, for example, transistors such as a Si metal-oxide-semiconductor field-effect transistor (Si MOSFET), a SiC MOSFET, or an insulated gate bipolar transistor (IGBT). The gate driver 10 of the present embodiment applies a drive voltage signal to the gate of the switching element 501. The switching elements 501 and 502 described hereafter are SiC MOSFETs.

A gate driver 10 is provided for each of the switching elements 501 and 502 to separately drive the switching elements 501 and 502. For the sake of simplicity, the description of the present embodiment will focus on the gate driver 10 that drives the switching element 501.

The gate driver 10 includes a low-voltage circuit 20 to which a first voltage V1 is applied, a high-voltage circuit 30 to which a second voltage V2 that is higher than the first voltage V1 is applied, and a transformer 40 arranged between the low-voltage circuit 20 and the high-voltage circuit 30. The transformer 40 connects the low-voltage circuit 20 and the high-voltage circuit 30. The first voltage V1 and the second voltage V2 are DC voltages.

The gate driver 10 of the present embodiment is configured to transmit a signal from the low-voltage circuit 20 via the transformer 40 to the high-voltage circuit 30 in response to a control signal from the ECU 503, and output a drive voltage signal from the high-voltage circuit 30.

The signal transmitted from the low-voltage circuit 20 to the high-voltage circuit 30, or the signal output from the low-voltage circuit 20 is, for example, a signal used to drive the switching element 501 such as a set signal or a reset signal. The set signal is a signal that transmits a rising edge of a control signal from the ECU 503, and the reset signal is a signal that transmits a falling edge of a control signal from the ECU 503. Furthermore, the set signal and the reset signal are signals for generating a drive voltage signal of the switching element 501. Thus, the set signal and the reset signal correspond to a first signal.

More specifically, the low-voltage circuit 20 is configured to be operated when the first voltage V1 is applied to the low-voltage circuit 20. The low-voltage circuit 20 is electrically connected to the ECU 503 and generates a set signal and a reset signal in accordance with a control signal received from the ECU 503. For example, the low-voltage circuit 20 generates a set signal in response to a rising edge of a control signal and generates a reset signal in response to a falling edge of a control signal. The low-voltage circuit 20 transmits the generated set signal and reset signal toward the high-voltage circuit 30.

The high-voltage circuit 30 is configured to be operated when the second voltage V2 is applied to the high-voltage circuit 30. The high-voltage circuit 30 is electrically connected to the gate of the switching element 501. The high-voltage circuit 30 generates a drive voltage signal for driving the switching element 501 in accordance with the set signal and the reset signal received from the low-voltage circuit 20 to apply a drive voltage signal to the gate of the switching element 501. Thus, the high-voltage circuit 30 generates a drive voltage signal that is applied to the gate of the switching element 501 based on the first signal output from the low-voltage circuit 20. The high-voltage circuit 30 generates a drive voltage signal for turning on the switching element 501 in response to a set signal and applies the drive voltage signal to the gate of the switching element 501. The high-voltage circuit 30 generates a drive voltage signal for turning off the switching element 501 in response to a reset signal and applies the drive voltage signal to the gate of the switching element 501. In this manner, the gate driver 10 on-off controls the switching element 501.

The high-voltage circuit 30 includes, for example, an RS type flip-flop circuit, which receives a set signal and a reset signal, and a driver, which generates a drive voltage signal in accordance with the output signal of the RS type flip-flop circuit. The specific circuit configuration of the high-voltage circuit 30 may be changed in any manner.

In the gate driver 10 of the present embodiment, the transformer 40 insulates the low-voltage circuit 20 and the high-voltage circuit 30. More specifically, the transformer 40 restricts transmission of DC voltage between the low-voltage circuit 20 and the high-voltage circuit 30 but allows transmission of various signals, such as the set signal and the reset signal.

Thus, a state in which the low-voltage circuit 20 is insulated from the high-voltage circuit 30 refers to a state in which the transmission of DC voltage is restricted between the low-voltage circuit 20 and the high-voltage circuit 30 and the transmission of a signal is permitted between the low-voltage circuit 20 and the high-voltage circuit 30.

The dielectric breakdown voltage of the gate driver 10 is, for example, 2500 Vrms or greater and 7500 Vrms or less. In the gate driver 10 of the present embodiment, the dielectric breakdown voltage is approximately 5000 Vrms. The dielectric breakdown voltage of the gate driver 10 is, however, not limited to any specific numerical value.

In the present embodiment, ground GND1 of the low-voltage circuit 20 is independent from ground GND2 of the high-voltage circuit 30. The potential at the ground GND1 of the low-voltage circuit 20 is referred to as a first reference potential, and the potential at the ground GND2 of the high-voltage circuit 30 is referred to as a second reference potential. In this case, the first voltage V1 is derived from the first reference potential, and the second voltage V2 is derived from the second reference potential. The first voltage V1 is, for example, 4.5 V or greater and 5.5 V or less. The second voltage V2 is, for example, 9 V or greater and 24 V or less.

The transformer 40 will now be described in detail.

The gate driver 10 of the present embodiment includes two transformers 40 and two capacitors 50 in correspondence with the two signals transmitted from the low-voltage circuit 20 to the high-voltage circuit 30. More specifically, the gate driver 10 includes a transformer 40 and a capacitor 50 that are used to transmit a set signal (SET), and a transformer 40 and a capacitor 50 that are used to transmit a reset signal (RESET). In the description hereafter, to facilitate understanding, the transformer 40 and the capacitor 50 used to transmit the set signal will be referred to as the transformer 40A and the capacitor 50A. Further, the transformer 40 and the capacitor 50 used to transmit the reset signal will be referred to as the transformer 40B and the capacitor 50B.

The gate driver 10 includes a low-voltage signal line 21A, which connects the low-voltage circuit 20 and the transformer 40A, and a low-voltage signal line 21B, which connects the low-voltage circuit 20 and the transformer 40B. Thus, the low-voltage signal line 21A transmits a set signal from the low-voltage circuit 20 to the transformer 40A. The low-voltage signal line 21B transmits a reset signal from the low-voltage circuit 20 to the transformer 40B.

The gate driver 10 includes a high-voltage signal line 31A, which connects the transformer 40A and the high-voltage circuit 30, and a high-voltage signal line 31B, which connects the transformer 40B and the high-voltage circuit 30. Thus, the high-voltage signal line 31A transmits a set signal from the transformer 40A to the high-voltage circuit 30. The high-voltage signal line 31B transmits a reset signal from the transformer 40B to the high-voltage circuit 30.

The transformer 40A transmits a set signal from the low-voltage circuit 20 to the high-voltage circuit 30 and insulates the low-voltage circuit 20 from the high-voltage circuit 30.

The transformer 40A includes a first coil 41A and a second coil 42A. The first coil 41A and the second coil 42A are electrically insulated from each other and are configured to be magnetically coupled to each other.

The first coil 41A is connected to the low-voltage circuit 20 by the low-voltage signal line 21A and to the ground GND1 of the low-voltage circuit 20. More specifically, the first coil 41A includes a first end electrically connected to the low-voltage circuit 20. The first coil 41A is configured to allow for application of a low voltage to the first end of the first coil 41A. The first coil 41A includes a second end electrically connected to the ground GND1 of the low-voltage circuit 20. Thus, the potential at the second end of the first coil 41A will be the first reference potential. The first reference potential is, for example, 0 V.

The second coil 42A is connected to the high-voltage circuit 30 by the high-voltage signal line 31A and to the ground GND2 of the high-voltage circuit 30. More specifically, the second coil 42A includes a first end electrically connected to the high-voltage circuit 30. The second coil 42A is configured to allow for application of a high voltage to the first end of the second coil 42A. The second coil 42A includes a second end electrically connected to the ground GND2 of the high-voltage circuit 30. Thus, the potential at the second end of the second coil 42A will be the second reference potential. The ground GND2 of the high-voltage circuit 30 is connected to the source of the switching element 501. Therefore, the second reference potential varies when the inverter device 500 is driven and may become, for example, 600 V or greater.

The transformer 40B transmits a reset signal from the low-voltage circuit 20 to the high-voltage circuit 30 and insulates the low-voltage circuit 20 from the high-voltage circuit 30. The transformer 40B includes a first coil 41B and a second coil 42B. The first coil 41B and the second coil 42B are electrically insulated from each other and are configured to be magnetically coupled to each other. The connection configuration of the transformer 40B is similar to the connection configuration of the transformer 40A and thus will not be described in detail.

The capacitor 50A is connected to the transformer 40A. More specifically, the capacitor 50A is connected between the first coil 41A and the second coil 42A of the transformer 40A.

The capacitor 50A includes a first capacitor electrode 51A and a second capacitor electrode 52A. The first capacitor electrode 51A and the second capacitor electrode 52A are located between the first coil 41A and the second coil 42A of the transformer 40A. The first capacitor electrode 51A is connected to the second end of the first coil 41A, and the second capacitor electrode 52A is connected to the second end of the second coil 42A. The second end of the first coil 41A is connected to the ground GND1 of the low-voltage circuit 20. In other words, the second end of the first coil 41A is a ground terminal. Therefore, the first capacitor electrode 51A is connected to the ground terminal of the first coil 41A. The second end of the second coil 42A is connected to the ground GND2 of the high-voltage circuit 30. In other words, the second end of the second coil 42A is a ground terminal. Therefore, the second capacitor electrode 52A is connected to the ground terminal of the second coil 42A.

The capacitor 50B is connected to the transformer 40B. More specifically, the capacitor 50B is connected between the first coil 41B and the second coil 42B of the transformer 40B.

The capacitor 50B includes a first capacitor electrode 51B and a second capacitor electrode 52B. The first capacitor electrode 51B and the second capacitor electrode 52B are located between the first coil 41B and the second coil 42B of the transformer 40B. The first capacitor electrode 51B is connected to the ground terminal of the first coil 41B. The second capacitor electrode 52B is connected to the ground terminal of the second coil 42B.

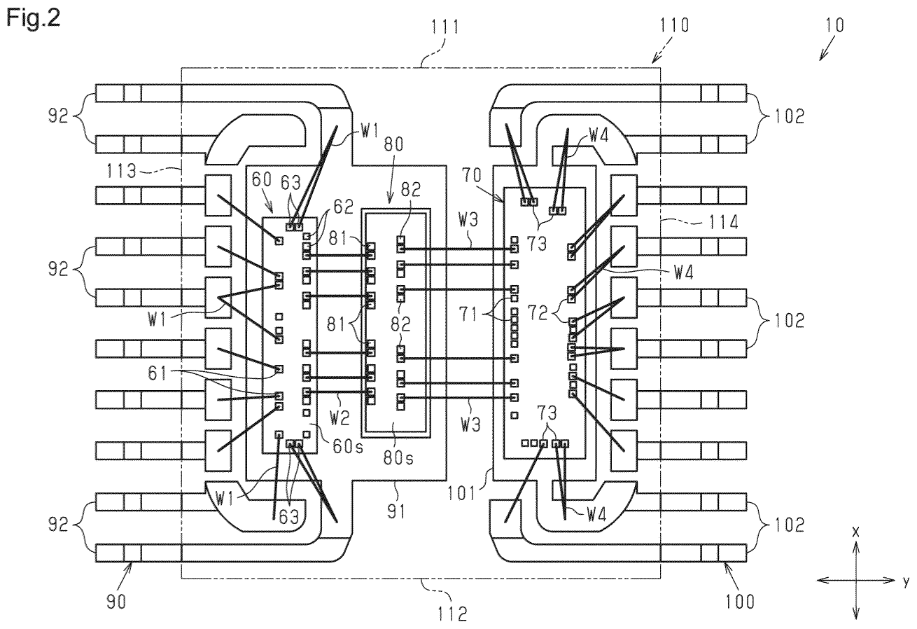

FIG. 2 is a plan view illustrating one example of the internal structure of the gate driver 10. FIG. 1 shows the circuit configuration of the gate driver 10 in a simplified manner. Thus, the number of external terminals of the gate driver 10 shown in FIG. 2 is greater than the number of external terminals of the gate driver 10 shown in FIG. 1. The number of external terminals of the gate driver 10 refers to the number of external electrodes that allow the gate driver 10 to be connected to electronic components located outside the gate driver 10 such as the ECU 503 and the switching element 501 (refer to FIG. 1). Further, in the gate driver 10 illustrated in FIG. 2, the number of signal lines (number of wires W1 to W4 that will be described later) transmitting signals from the low-voltage circuit 20 to the high-voltage circuit 30 is greater than the number of signal lines of the gate driver 10 illustrated in FIG. 1.

As shown in FIG. 2, the gate driver 10 is a semiconductor device, which is a single package of semiconductor chips, and mounted on a circuit substrate of the inverter device 500. The switching elements 501 and 502 are mounted on a mounting substrate that is separate from the above circuit substrate. A cooling device is attached to the mounting substrate.

The gate driver 10, which is of a small outline (SO) package type, is a small outline package (SOP) in the present embodiment. The gate driver 10 includes a low-voltage circuit chip 60, a high-voltage circuit chip 70, a transformer chip 80, a low-voltage lead frame 90, a high-voltage lead frame 100, and mold resin 110. The low-voltage circuit chip 60, the high-voltage circuit chip 70, and the transformer chip 80 are semiconductor chips. The low-voltage circuit chip 60 is mounted on the low-voltage lead frame 90. The high-voltage circuit chip 70 is mounted on the high-voltage lead frame 100. The mold resin 110 encapsulates parts of the lead frames 90 and 100 and each of the chips 60, 70, and 80. In the present embodiment, the transformer chip 80 corresponds to an insulating transformer. The transformer chip 80 and the mold resin 110 correspond to an insulating module that insulates the low-voltage circuit 20 and the high-voltage circuit 30. In FIG. 2, the mold resin 110 is shown in double-dashed lines so that the internal structure of the gate driver 10 can be shown. The gate driver 10 may be of any package type.

The mold resin 110 is formed from an electrically insulative material. The resin is, for example, a black epoxy resin. The mold resin 110 has a rectangular form of which the thickness direction is a z-direction. The mold resin 110 includes four resin side surfaces 111 to 114. More specifically, the mold resin 110 includes resin side surfaces 111 and 112, which are the two end surfaces in an x-direction, and resin side surfaces 113 and 114, which are the two end surfaces in a y-direction. The x-direction and the y-direction are orthogonal to the z-direction. The x-direction and the y-direction are orthogonal to each other. In the description hereafter, a plan view refers to a view taken in the z-direction.

The low-voltage lead frame 90 and the high-voltage lead frame 100 are each formed from a conductive material. The low-voltage lead frame 90 and the high-voltage lead frame 100 are formed from a material including copper (Cu), iron (Fe), or the like. The lead frames 90 and 100 extend from the inside to the outside of the mold resin 110.

The low-voltage lead frame 90 includes a low-voltage die pad 91, which is arranged in the mold resin 110, and low-voltage leads 92, which extend from the inside to the outside of the mold resin 110. The low-voltage leads 92 form external terminals electrically connected to external electronic devices such as the ECU 503 (refer to FIG. 1).

In the present embodiment, the low-voltage circuit chip 60 and the transformer chip 80 are both mounted on the low-voltage die pad 91. In plan view, the low-voltage die pad 91 is arranged so that its central part in the y-direction is closer to the resin side surface 113 than the central part of the mold resin 110 in the y-direction. In the present embodiment, the low-voltage die pad 91 is not exposed from the mold resin 110. The low-voltage die pad 91 has a rectangular form in plan view so that its long sides extend in the x-direction and its short sides extend in the y-direction.

The low-voltage leads 92 are arranged separated from one another in the x-direction. The low-voltage leads 92 arranged at the two ends of the arrangement of the low-voltage leads 92 in the x-direction are each integrated with the low-voltage die pad 91. Part of each low-voltage lead 92 projects out of the mold resin 110 from the resin side surface 113.

The high-voltage lead frame 100 includes a high-voltage die pad 101, which is arranged in the mold resin 110, and high-voltage leads 102, which extend from the inside to the outside of the mold resin 110. The high-voltage leads 102 form external terminals electrically connected to external electronic devices such as the gate of the switching element 501 (refer to FIG. 1).

The high-voltage circuit chip 70 is mounted on the high-voltage die pad 101. In plan view, the high-voltage die pad 101 is located closer to the resin side surface 114 than the low-voltage die pad 91 in the y-direction. In the present embodiment, the high-voltage die pad 101 is not exposed from the mold resin 110. The high-voltage die pad 101 has a rectangular form in plan view so that its long sides extend in the x-direction and its short sides extend in the y-direction.

The low-voltage die pad 91 and the high-voltage die pad 101 are arranged separated from each other in the y-direction. Thus, the y-direction is the arrangement direction of the two die pads 91 and 101.

The dimensions of the low-voltage die pad 91 and the high-voltage die pad 101 in the y-direction are determined in accordance with the size and quantity of the mounted semiconductor chips. In the present embodiment, the low-voltage circuit chip 60 and the transformer chip 80 are mounted on the low-voltage die pad 91, and the high-voltage circuit chip 70 is mounted on the high-voltage die pad 101. Thus, the dimension of the low-voltage die pad 91 in the y-direction is greater than the dimension of the high-voltage die pad 101 in the y-direction.

The high-voltage leads 102 are arranged separated from one another in the x-direction. Two of the high-voltage leads 102 are integrated with the high-voltage die pad 101. Part of each high-voltage lead 102 projects out of the mold resin 110 from the resin side surface 114.

In the present embodiment, the number of the high-voltage leads 102 is the same as the number of the low-voltage leads 92. As shown in FIG. 2, the low-voltage leads 92 and the high-voltage leads 102 are arranged in a direction (x-direction) orthogonal to the arrangement direction (y-direction) of the low-voltage die pad 91 and the high-voltage die pad 101. The number of the high-voltage leads 102 and the number of the low-voltage leads 92 may be freely changed.

In the present embodiment, the low-voltage die pad 91 is supported by the two low-voltage leads 92 integrated with the low-voltage die pad 91. The high-pressure die pad 101 is supported by the two high-pressure leads 102 integrated with the high-pressure die pad 101. Each of the die pads 91 and 101 do not include suspended leads exposed from the resin side surfaces 111 and 112. This allows the low-voltage lead frame 90 and the high-voltage lead frame 100 to be spaced apart by a long insulating distance.

The low-voltage circuit chip 60, the high-voltage circuit chip 70, and the transformer chip 80 are arranged separated from one another in the y-direction. The low-voltage circuit chip 60, the transformer chip 80, and the high-voltage circuit chip 70 are arranged in order from the low-voltage leads 92 to the high-voltage leads 102 in the y-direction.

The low-voltage circuit chip 60 includes the low-voltage circuit 20 shown in FIG. 1. The low-voltage circuit chip 60 has a rectangular form in plan view and includes short sides and long sides. In plan view, the low-voltage circuit chip 60 is mounted on the low-voltage die pad 91 so that the long sides extend in the x-direction and the short sides extend in the y-direction. The low-voltage circuit chip 60 includes a chip main surface 60s and a chip back surface (not shown) at opposite sides in the z-direction. The chip back surface of the low-voltage circuit chip 60 is bonded by a conductive bonding material, such as a silver (Ag) paste, to the low-voltage die pad 91.

First electrode pads 61, second electrode pads 62, and third electrode pads 63 are formed on the chip main surface 60s of the low-voltage circuit chip 60. The electrode pads 61 to 63 are electrically connected to the low-voltage circuit 20.

The first electrode pads 61 are located on the chip main surface 60s closer to the low-voltage leads 92 than the central part of the chip main surface 60s in the y-direction. The first electrode pads 61 are arranged in the x-direction. The second electrode pads 62 are located at the one of the two ends of the chip main surface 60s in the y-direction that is closer to the transformer chip 80. The second electrode pads 62 are arranged in the x-direction. The third electrode pads 63 are located at the two ends of the chip main surface 60s in the x-direction.

The high-voltage circuit chip 70 includes the high-voltage circuit 30 shown in FIG. 1. The high-voltage circuit chip 70 has a rectangular form in plan view and includes short sides and long sides. In plan view, the high-voltage circuit chip 70 is mounted on the high-voltage die pad 101 so that the long sides extend in the x-direction and the short sides extend in the y-direction. The high-voltage circuit chip 70 includes a chip main surface 70s and a chip back surface (not shown) at opposite sides in the z-direction. The chip back surface of the high-voltage circuit chip 70 is bonded by a conductive bonding material to the high-voltage die pad 101.

First electrode pads 71, second electrode pads 72, and third electrode pads 73 are formed on the chip main surface 70s of the high-voltage circuit chip 70. The electrode pads 71 to 73 are electrically connected to the high-voltage circuit 30.

The first electrode pads 71 are located at the one of the two ends of the chip main surface 70s in the y-direction that is closer to the transformer chip 80. The first electrode pads 71 are arranged in the x-direction. The second electrode pads 72 are located at the one of the two ends of the chip main surface 70s in the y-direction that is farther from the transformer chip 80. Thus, the second electrode pads 72 are located at the one of the two ends of the chip main surface 70s in the y-direction that is closer to the high-voltage leads 102. The second electrode pads 72 are arranged in the x-direction. The third electrode pads 73 are located at the two ends of the chip main surface 70s in the x-direction.

The transformer chip 80 includes the transformer 40 (40A, 40B) and the capacitor 50 (50A, 50B) shown in FIG. 1. The transformer chip 80 has a rectangular form in plan view and include short sides and long sides. In the present embodiment, in plan view, the transformer chip 80 is mounted on the low-voltage die pad 91 so that the long sides extend in the x-direction and the short sides extend in the y-direction.

The transformer chip 80 is located next to the low-voltage circuit chip 60 in the y-direction. The transformer chip 80 is located closer to the high-voltage circuit chip 70 than the low-voltage circuit chip 60. Thus, the transformer chip 80 is located between the low-voltage circuit chip 60 and the high-voltage circuit chip 70 in the y-direction.

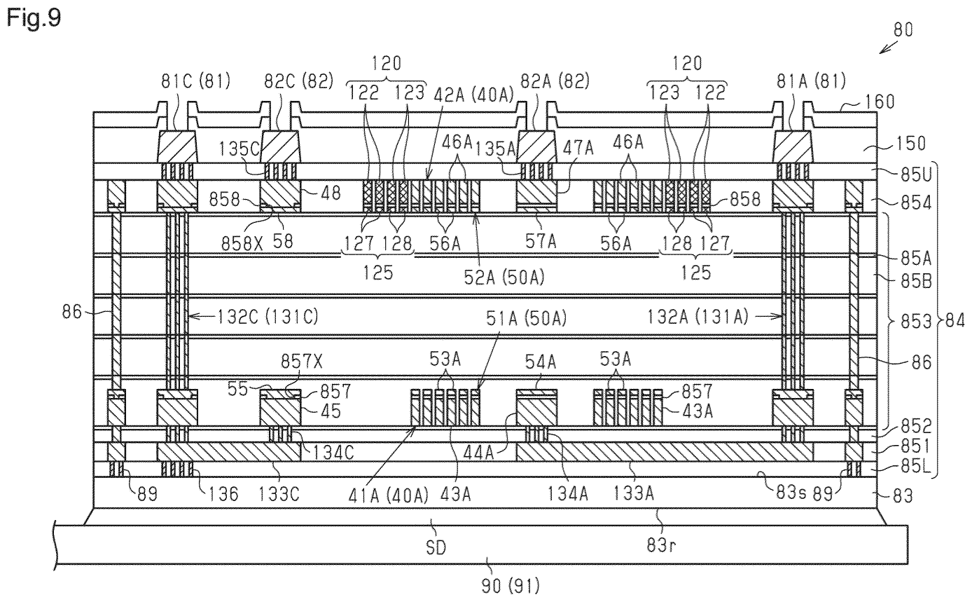

The transformer chip 80 includes a chip main surface 80s and a chip back surface 80r (refer to FIG. 9) at opposite sides in the z-direction. The chip back surface 80r of the transformer chip 80 is bonded by a conductive bonding material SD (refer to FIG. 9) to the low-voltage die pad 91.

As shown in FIG. 2, the chip main surface 80s of the transformer chip 80 includes first electrode pads 81 and second electrode pads 82. In the present embodiment, each first electrode pad 81 corresponds to a first electrode and each second electrode pad 82 corresponds to a second electrode.

The first electrode pads 81 are located at, for example, the one of the two ends of the chip main surface 80s in the y-direction that is closer to the low-voltage circuit chip 60. The first electrode pads 81 are arranged in the x-direction. The second electrode pads 82 are located, for example, near the central part of the chip main surface 80s in the y-direction. The second electrode pads 82 are arranged in the x-direction.

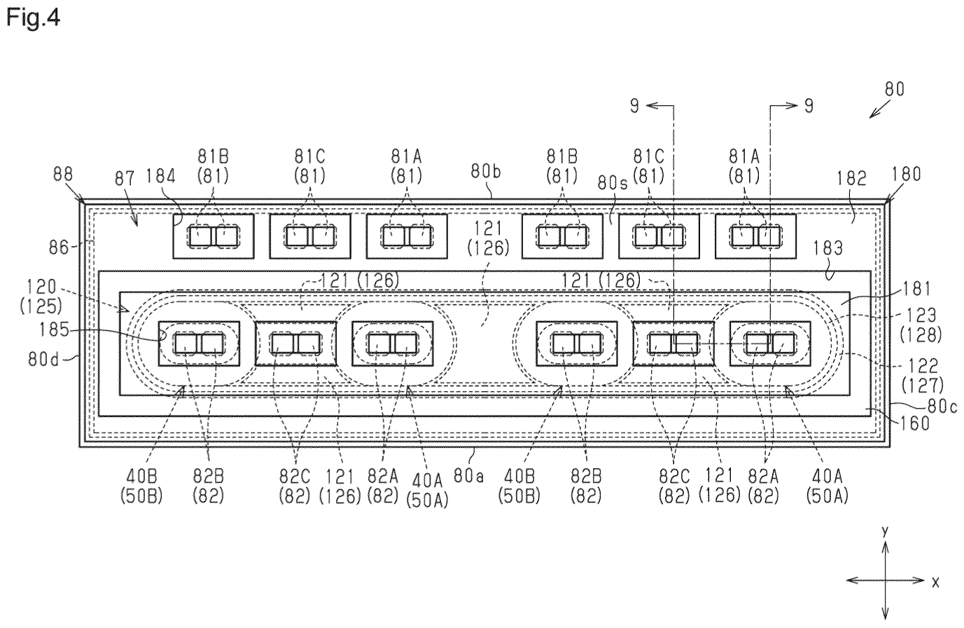

As shown in FIG. 4, in plan view, the transformers 40A and 40B and the capacitors 50A and 50B are located near the central part of the chip main surface 80s in the y-direction. In plan view, the second electrode pads 82 are located at positions separated from the transformers 40A and 40B and the capacitors 50A and 50B. The electrode pads 81 and 82 are electrically connected to the transformers 40A and 40B and the capacitors 50A and 50B.

Referring to FIG. 2, the low-voltage die pad 91 and the high-voltage die pad 101 where the lead frames 90 and 100 are the closest have to be separated from each other to set the dielectric breakdown voltage of the gate driver 10 to the preset dielectric breakdown voltage. Thus, the distance between the high-voltage circuit chip 70 and the transformer chip 80 is greater than the distance between the low-voltage circuit chip 60 and the transformer chip 80 in plan view.

Wires W1 to W4 are connected to the low-voltage circuit chip 60, the transformer chip 80, and the high-voltage circuit chip 70. The wires W1 to W4 are bonding wires formed by a wire bonding device from a material including, for example, gold (Au), aluminum (Al), copper (Cu), or the like.

The low-voltage circuit chip 60 is electrically connected by wires W1 to the low-voltage lead frame 90. More specifically, the first electrode pads 61 and the third electrode pads 63 of the low-voltage circuit chip 60 are connected to the low-voltage leads 92 by wires W1. The third electrode pads 63 of the low-voltage circuit chip 60 are connected by wires W1 to the two low-voltage leads 92 integrated with the low-voltage die pad 91. This electrically connects the low-voltage circuit 20 to the low-voltage leads 92 (ones of external electrodes of gate driver 10 electrically connected to ECU 503). In the present embodiment, the two low-voltage leads 92 integrated with the low-voltage die pad 91 form ground terminals, and the wires W1 electrically connect the low-voltage circuit 20 and the low-voltage die pad 91. Thus, the potential at the low-voltage die pad 91 is the same as that at ground GND1 of the low-voltage circuit 20.

The high-voltage circuit chip 70 is connected by wires W4 to the high-voltage leads 102 of the high-voltage lead frame 100. More specifically, the second electrode pads 72 and the third electrode pads 73 of the high-voltage circuit chip 70 are connected to the high-voltage leads 102 by the wires W4. This electrically connects the high-voltage circuit 30 to the high-voltage leads 102 (ones of external electrodes of gate driver 10 electrically connected to switching element 501 or the like). In the present embodiment, the two high-voltage leads 102 integrated with the high-voltage die pad 101 form ground terminals, and the wires W4 electrically connect the high-voltage circuit 30 and the high-voltage die pad 101. Thus, the potential at the high-voltage die pad 101 is the same as that at ground GND2 of the high-voltage circuit 30.

The transformer chip 80 is connected to the low-voltage circuit chip 60 by wires W2 and connected to the high-voltage circuit chip 70 by wires W3. More specifically, the first electrode pads 81 of the transformer chip 80 are connected to the second electrode pads 62 of the low-voltage circuit chip 60 by the wires W2. The second electrode pads 82 of the transformer chip 80 are connected to the first electrode pads 71 of the high-voltage circuit chip 70 by the wires W3.

The first coil 41A of the transformer 40A and the first coil 41B of the transformer 40B (refer to FIG. 1) are both connected by the wires W2, the low-voltage circuit chip 60, and the like to ground GND1 of the low-voltage circuit 20. The second coil 42A of the transformer 40A and the second coil 42B of the transformer 40B (refer to FIG. 1) are both connected by the wires W3, the high-voltage circuit chip 70, and the like to ground GND2 of the high-voltage circuit 30.

Configuration of Transformer Chip

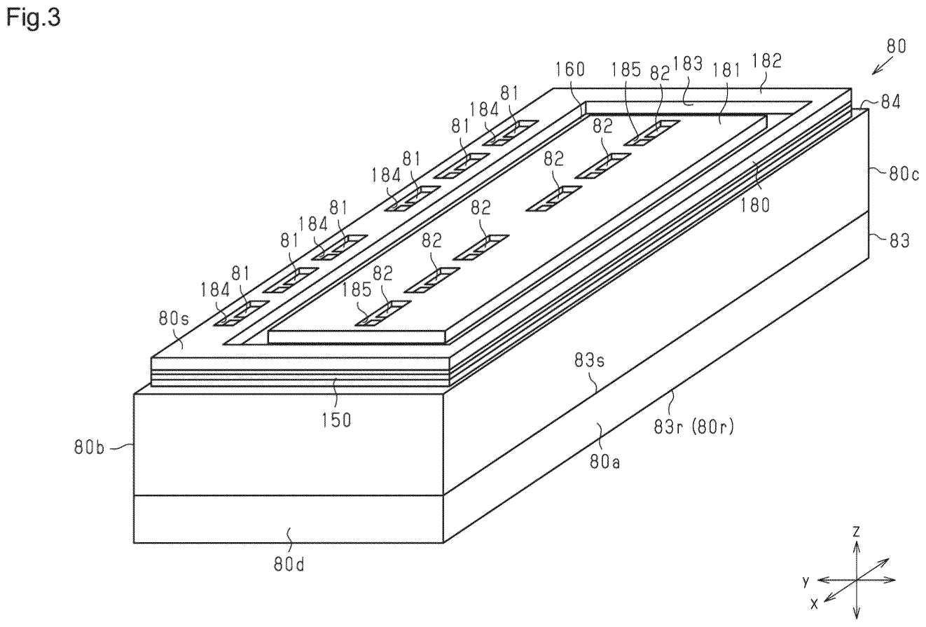

An example of the configuration of the transformer chip 80 will now be described with reference to FIGS. 3 to 9.

In the description hereafter, the direction extending from the chip back surface 80r toward the chip main surface 80s of the transformer chip 80 will be referred to as the upward direction, and the direction extending from the chip main surface 80s toward the chip back surface 80r will be referred to as the downward direction.

FIG. 3 is a perspective view showing the transformer chip 80.

FIG. 4 is a plan view of the transformer chip 80 and shows the transformers 40A and 40B and the capacitors 50A and 50B in broken lines to aid understanding. A shield electrode 86 and dummy patterns 120 and 125, which will be described later, are also shown in broken lines.

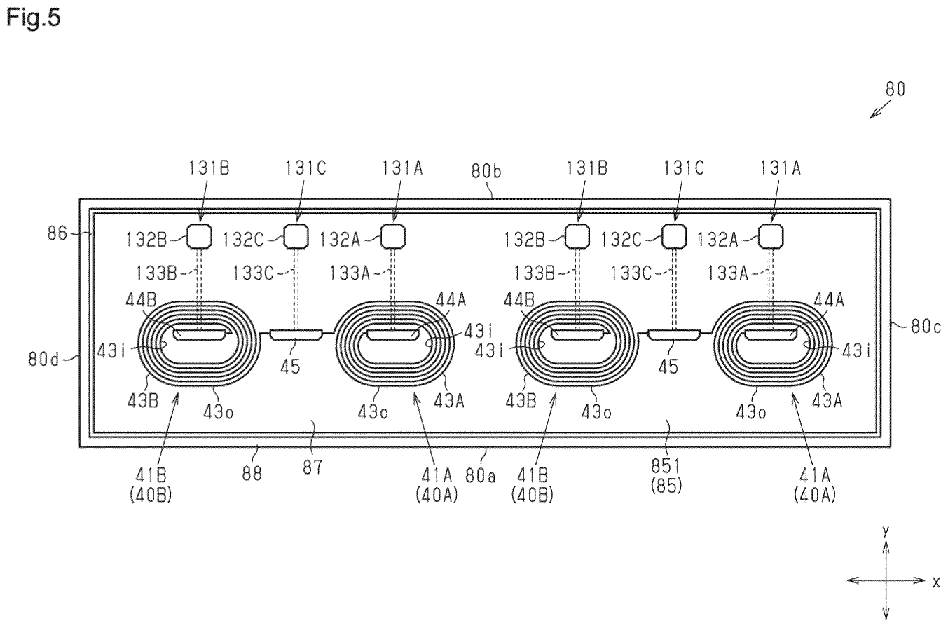

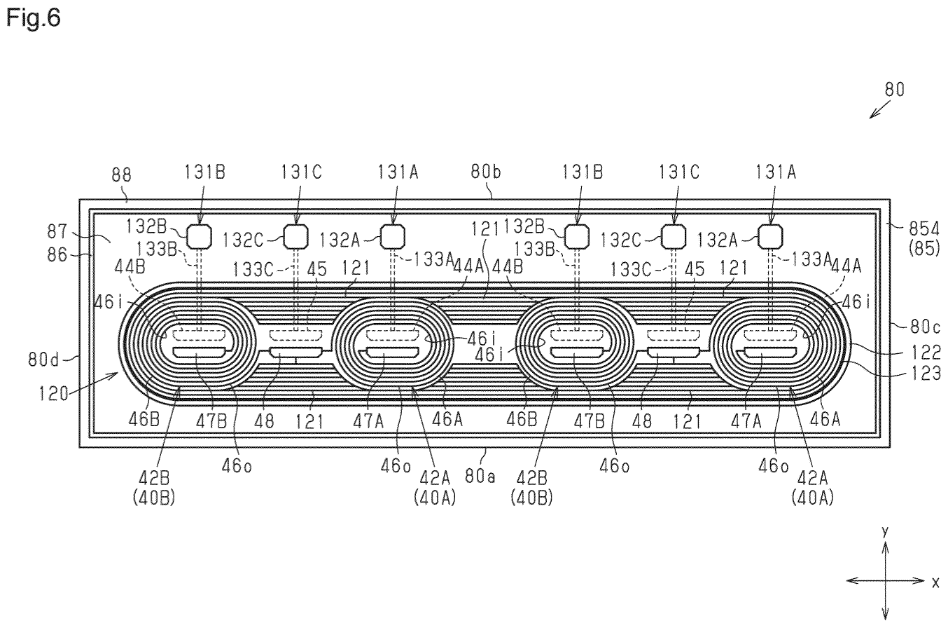

FIG. 5 is a cross-sectional view of the transformer chip 80 taken along an xy plane at where the first coils 41A and 41B are located in the z-direction and shows the connection relationship of the first coils 41A and 41B. FIG. 6 is a cross-sectional view of the transformer chip 80 taken along an xy plane at where the second coils 42A and 42B are located in the z-direction and shows the connection relationship of the second coils 42A and 42B. Hatching lines are not shown in FIGS. 5 and 6 for the sake of simplicity.

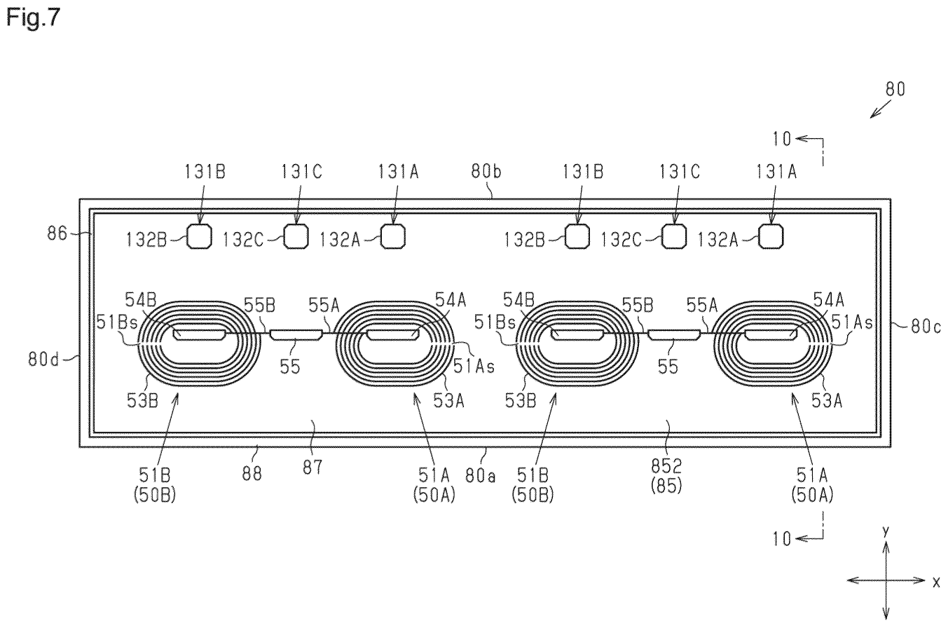

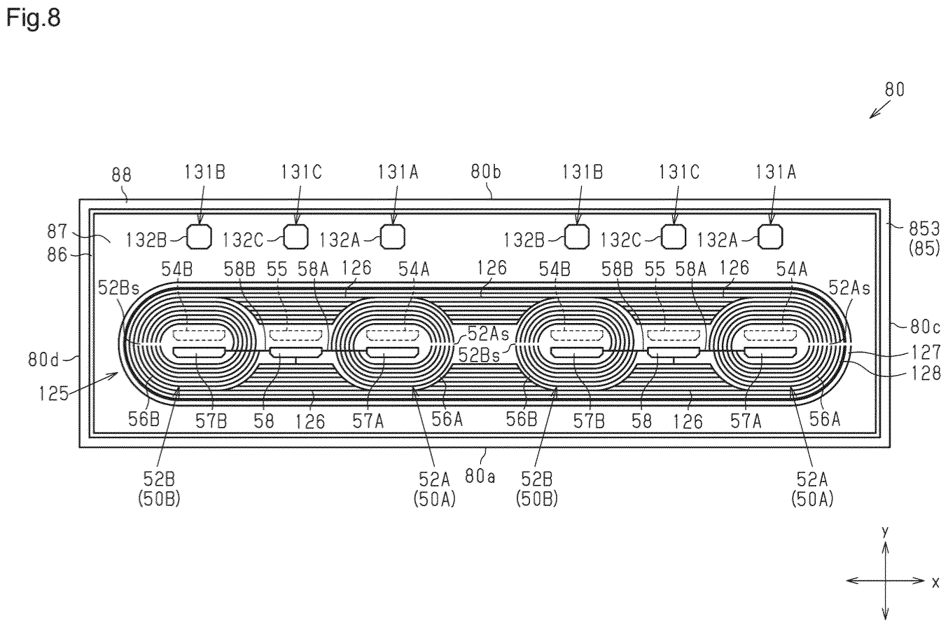

FIG. 7 is a cross-sectional view of the transformer chip 80 taken along an xy plane at where the first capacitor electrodes 51A and 51B are located in the z-direction. FIG. 8 is a cross-sectional view of the transformer chip 80 taken along an xy plane at where the second capacitor electrodes 52A and 52B are located in the z-direction. Hatching lines are not shown in FIGS. 7 and 8 for the sake of simplicity.

FIG. 9 is a cross-sectional view of the transformer chip 80 taken along line 9-9 in FIG. 4 and shows the cross-sectional structure of the transformer 40A and the capacitor. Some of the hatching lines are not shown in FIG. 9 to aid understanding.

As shown in FIG. 4, the transformer chip 80 of the present embodiment two pairs of the transformers 40A and 40B and two pairs of the capacitors 50A and 50B. More specifically, the transformer chip 80 is a semiconductor chip integrating the transformers 40A and 40B and the capacitors 50A and 50B on the same chip. The transformer chip 80 is separate from the low-voltage circuit chip 60 and the high-voltage circuit chip 70 (refer to FIG. 2).

The transformers 40A and 40B of each pair have the same structure as the capacitors 50A and 50B of each pair. Further, the transformer 40B has the same structure as the transformer 40A. The capacitor 50B also has the same structure as the capacitor 50A. Accordingly, the structures of the transformer 40A and the capacitor 50A will be described in detail, and the transformer 40B and the capacitor 50B will not be described.

As shown in FIG. 4, the transformer chip 80 includes four chip side surfaces 80a, 80b, 80c, and 80d that are orthogonal to both the chip main surface 80s and the chip back surface 80r. The chip side surfaces 80a to 80d are located between the chip main surface 80s and the chip back surface 80r in the z-direction. The chip side surfaces 80a and 80b define the two end surfaces of the transformer chip 80 in the y-direction, and the chip side surfaces 80c and 80d define the two end surfaces of the transformer chip 80 in the x-direction. In plan view, the chip side surfaces 80a and 80b are the long sides of the transformer chip 80, and the chip side surfaces 80c and 80d are the short sides of the transformer chip 80. In the present embodiment, the chip side surface 80a is closer than the chip side surface 80b to the high-voltage circuit chip 70 (refer to FIG. 2), and the chip side surface 80b is closer than the chip side surface 80a to the low-voltage circuit chip 60 (refer to FIG. 2).

As shown in FIGS. 4 and 9, the transformer chip 80 includes a substrate 83 and an insulation layer 84 formed on the substrate 83.

The substrate 83 is formed by, for example, a semiconductor substrate. The substrate 83 of the present embodiment is formed from a material containing silicon (Si). The semiconductor substrate 83 may be a semiconductor substrate of a wide bandgap semiconductor or a compound semiconductor. Further, instead of a semiconductor substrate, an insulative substrate formed from a material including glass may be used as the substrate 83.

A wide bandgap semiconductor is a semiconductor substrate having a band gap of 2.0 eV or greater. The wide bandgap semiconductor may be silicon carbide (SiC). A compound semiconductor may be a III-V compound semiconductor. The compound semiconductor may contain at least one of aluminum nitride (AlN), indium nitride (InN), gallium nitride (GaN), and gallium arsenide (GaAs).

The substrate 83 includes a substrate main surface 83s and a substrate back surface 83r at opposite sides in the z-direction. The substrate back surface 83r defines the chip back surface 80r of the transformer chip 80.

As shown in FIG. 9, the insulation layer 84 of the present embodiment includes insulation films 85L, 851 to 854, and 85U stacked from the substrate main surface 83s of the substrate 83 in the z-direction. Thus, the z-direction is also the thickness direction of the insulation layer 84. Further, the z-direction is the stacking direction of the insulation films 85L, 851 to 854, and 85U. The insulation layer 84 is formed on the substrate main surface 83s of the substrate 83. The structure of the insulation layer 84 may be changed.

The insulation films 851 to 854 and 85U are formed in this order on the lowermost insulation film 85L.

The insulation films 85L, 851 to 854, and 85U are formed from a material containing silicon (Si). The insulation films 85 may be a stack of the insulation films. The insulation films 85L, 851, 852, 854, and 85U may be formed from a material containing silicon oxide (SiO₂). The insulation film 853 may include thin films 85A, which are formed by a material containing silicon nitride (SiN), SiC, silicon carbon nitride (SiCN) or the like, and interlayer insulation films 85B, which are formed by a material containing SiO₂. The structure of each of the insulation films 85L, 851 to 854, and 85U may be changed.

The lowermost insulation film 85L is formed on the substrate 83 in contact with the substrate 83.

The shield electrode 86 of the transformer chip 80 is formed in the insulation layer 84. The shield electrode 86 limits the entrance of moisture into the insulation layer 84 and limits the formation of cracks in the insulation layer 84. The shield electrode 86 is arranged in the peripheral portion of the insulation layer 84 (peripheral portion of transformer chip 80) in plan view. More specifically, as shown in FIGS. 4 to 8, the shield electrode 86 is arranged separated from the chip side surfaces 80a to 80d. In plan view, the shield electrode 86 has the form of a strip and extends along the chip side surfaces 80a to 80d. In the present embodiment, the shield electrode 86 has the form of a rectangular loop in plan view. The shield electrode 86 partitions the insulation layer 84 into an inner region 87 and an outer region 88. In the present embodiment, as shown in FIG. 9, the uppermost insulation film 85U extends over the shield electrode 86 in plan view. Thus, the uppermost insulation film 85U includes the outer region 88.

As shown in FIG. 4, the inner region 87 of the insulation layer 84 is protected by the shield electrode 86. In plan view, the inner region 87 is rectangular and has long sides extending in the x-direction and short sides extending in the y-direction. The outer region 88 has the form of a rectangular loop in plan view and surrounds the inner region 87. The outer region 88 extends between the shield electrode 86 and the chip side surfaces 80a to 80d in plan view. Thus, the outer region 88 has the form of a rectangular loop and includes the chip side surfaces 80a to 80d.

As shown in FIG. 9, the shield electrode 86 extends through the insulation layer 84 in the z-direction. More specifically, the shield electrode 86 overlaps the coils 41A, 41B, 42A, and 42B of the transformers 40A and 40B and the capacitor electrodes 51A, 51B, 52A, and 52B of the capacitors 50A and 50B as viewed in a direction orthogonal to the z-direction. In the present embodiment, the shield electrode 86 extends from the insulation film 851 to the insulation film 854 in the z-direction. The shield electrode 86 is formed from a material containing one or more of titanium (Ti), titanium nitride (TiN), Au, Ag, Cu, Al, and tungsten (W).

The lowermost insulation film 85L includes a via 89 extending through the lowermost insulation film 85L in the z-direction. The via 89, which overlaps the shield electrode 86 in plan view, connects the shield electrode 86 and the substrate 83. This electrically connects the shield electrode 86 to the substrate 83. The via 89 may be formed from, for example, the same material as the shield electrode 86.

As shown in FIG. 4, the transformers 40A and 40B and the capacitors 50A and 50B are embedded in the insulation layer 84. The transformers 40A and 40B and the capacitors 50A and 50B are arranged in the inner region 87. As viewed in the z-direction, the capacitors 50A overlap the transformers 40A, and the capacitors 50B overlap the transformers 40B. The transformers 40A and 40B and the capacitors 50A and 50B are located at the same position in the y-direction and separated in the x-direction. The transformers 40A and 40B and the capacitors 50A and 50B are arranged in a direction orthogonal to the direction in which the chips 60, 70, and 80 are aligned.

As shown in FIG. 4, the pairs of the transformer 40A and the capacitor 50A are arranged in an alternating manner with the pairs of the transformer 40B and the capacitor 50B in the x-direction from the chip side surface 80c toward the chip side surface 80d.

As shown in FIG. 5, the first coil 41A of each transformer 40A includes first coil wiring 43A, a first ground terminal 45 connected to one end of the first coil wiring 43A, and a first signal terminal 44A connected to the other end of the first coil wiring 43A. The first coil 41B of each transformer 40B includes first coil wiring 43B, the first ground terminal 45 connected to one end of the first coil wiring 43B, and a first signal terminal 44B connected to the other end of the first coil wiring 43B. The first ground terminal 45 is shared by the first coil 41A and the first coil 41B. The first coil 41A may include a first ground terminal that is separate from that of the first coil 41B.

The first coil wirings 43A and 43B each have the form of an elliptical spiral in plan view. The first signal terminals 44A and 44B are located at the inner side of the first coil wiring 43A and 43B, respectively. The first ground terminal 45 is located between the first coil 41A of the transformer 40A and the first coil 41B of the transformer 40B. The first coils 41A and 41B are formed from a material containing Al.

The first signal terminal 44A is connected by connective wiring 131A to the corresponding first electrode pad 81A shown in FIG. 4. The first signal terminal 44B is connected by connective wiring 131B to the corresponding first electrode pad 81B shown in FIG. 4. The first ground terminal 45 is connected by connective wiring 131C to the corresponding first electrode pad 81C shown in FIG. 4.

As shown in FIG. 6, the second coil 42A of each transformer 40A includes second coil wiring 46A, a second ground terminal 48 connected to one end of the second coil wiring 46A, and a second signal terminal 47A connected to the other end of the second coil wiring 46A. The second coil 42B of each transformer 40B includes second coil wiring 46B, the second ground terminal 48 connected to one end of the second coil wiring 46B, and a second signal terminal 47B connected to the other end of the second coil wiring 46B. The second ground terminal 48 is shared by the second coil 42A and the second coil 42B. The second coil 42A may include a second ground terminal that is separate from that of the second coil 42B.

The second coil wirings 46A and 46B each have the form of an elliptical spiral in plan view. The second signal terminals 47A and 47B are located at the inner sides of the second coil wirings 46A and 46B, respectively. The second ground terminal 48 is located between the second coil 42A of the transformer 40A and the second coil 42B of the transformer 40B. The second coils 42A and 42B are formed from a material containing Al.

The second signal terminal 47A is connected to the corresponding second electrode pad 82A shown in FIG. 4. The second signal terminal 47B is connected to the corresponding second electrode pad 82B shown in FIG. 4. The second ground terminal 48 is connected to the corresponding second electrode pad 82C shown in FIG. 4.

In the present embodiment, in plan view, the winding direction of the second coil wiring 46A is the same as that of the first coil wiring 43A shown in FIG. 5. Further, the second coil wiring 46A has the same number of windings as the first coil wiring 43A. In the present embodiment, in plan view, the winding direction of the second coil wiring 46B is the same as that of the first coil wiring 43B shown in FIG. 5. Further, the second coil wiring 46B has the same number of windings as the first coil wiring 43B.

In plan view, the first capacitor electrode 51A of each capacitor 50A shown in FIG. 7 overlaps the corresponding first coil 41A shown in FIG. 5. The first capacitor electrode 51A is formed from a conductive material. Preferably, the first capacitor electrode 51A is formed from a non-magnetic material. The non-magnetic material is one or more of Ti, TiN, tungsten titanium (TiW), tantalum (Ta), tantalum nitride (TaN), chromium (Cr), chromium silicide (CrSi), Au, Ag, Cu, Al, and W. The first capacitor electrode 51A may be formed from a conductive material other than those described above. The first capacitor electrode 51A of the present embodiment is formed from a material containing TiN.

Each first capacitor electrode 51A includes first electrode wiring 53A, a first capacitor terminal 54A, and a first capacitor ground terminal 55. The first electrode wiring 53A has the form of an elliptical spiral like the first coil wiring 43A shown in FIG. 5. The first electrode wiring 53A is identical in shape to the first coil wiring 43A of the first coil 41A shown in FIG. 5. More specifically, the first electrode wiring 53A has a line width-to-line interval ratio that is the same as that of the first coil wiring 43A.

The first electrode wiring 53A includes a first slit 51As extending from the center of the first electrode wiring 53A toward the outer side of the first electrode wiring 53A. The first electrode wiring 53A has the form of an open loop because of the first slit 51As. The first slit 51As restricts the formation of a current loop in the first electrode wiring 53A.

The first capacitor terminal 54A is arranged overlapping the first signal terminal 44A of the corresponding first coil 41A shown in FIG. 5. The first capacitor terminal 54A is identical in shape to the first signal terminal 44A in plan view. The first capacitor terminal 54A is located at the inner side of the first electrode wiring 53A and connected to the first electrode wiring 53A. The first capacitor terminal 54A may have any shape. Further, the first capacitor terminal 54A may be omitted.

Each first capacitor ground terminal 55 is arranged overlapping the corresponding first ground terminal 45 of the first coil 41A shown in FIG. 5. The first capacitor ground terminal 55 is identical in shape to the first ground terminal 45 in plan view. The first capacitor ground terminal 55 is located between the first capacitor electrode 51A of the capacitor 50A and the first capacitor electrode 51B of the capacitor 50B. The first capacitor ground terminal 55 is electrically connected by connective wiring 55A, which extends toward the center of the first electrode wiring 53A, to each wiring portion of the first electrode wiring 53A.

In plan view, the first capacitor electrode 51B of the capacitor 50B shown in FIG. 7 overlaps the first coil 41B shown in FIG. 5. The first capacitor electrode 51B is formed from a conductive material. Preferably, the first capacitor electrode 51B is formed from a non-magnetic material. The non-magnetic material is one or more of Ti, TiN, TiW, Ta, TaN, Cr, CrSi, Au, Ag, Cu, Al, and W. The first capacitor electrode 51B may be formed from a conductive material other than those described above. The first capacitor electrode 51B of the present embodiment is formed from a material containing TiN.

Each first capacitor electrode 51B includes first electrode wiring 53B, a first capacitor terminal 54B, and the first capacitor ground terminal 55. In the same manner as the first coils 41A and 41B shown in FIG. 5, the first capacitor electrodes 51A and 51B share the first capacitor ground terminal 55.

The first electrode wiring 53B has the form of an elliptical spiral like the first coil wiring 43B shown in FIG. 5. The first electrode wiring 53B is identical in shape to the first coil wiring 43B of the first coil 41B shown in FIG. 5. More specifically, the first electrode wiring 53B has a line width-to-line interval ratio that is the same as that of the first coil wiring 43B. The first electrode wiring 53B includes a first slit 51Bs extending from the center of the first electrode wiring 53B toward the outer side of the first electrode wiring 53B. The first electrode wiring 53B has the form of an open loop because of the first slit 51Bs. The first slit 51Bs restricts the formation of a current loop in the first electrode wiring 53B.

The first capacitor terminal 54B is arranged overlapping the first signal terminal 44B of the corresponding first coil 41B shown in FIG. 5. The first capacitor terminal 54B is identical in shape to the first signal terminal 44B in plan view. The first capacitor terminal 54B is located at the inner side of the first electrode wiring 53B and connected to the first electrode wiring 53B. The first capacitor terminal 54B may have any shape. Further, the first capacitor terminal 54A may be omitted.

The first capacitor ground terminal 55 is electrically connected by connective wiring 55B, which extends toward the center of the first electrode wiring 53B, to each wiring portion of the first electrode wiring 53B.

In plan view, the second capacitor electrode 52A of the capacitor 50A shown in FIG. 8 overlaps the second coil 42A shown in FIG. 6. The second capacitor electrode 52A is formed from a conductive material. Preferably, the second capacitor electrode 52A is formed from a non-magnetic material. The non-magnetic material is one or more of Ti, TiN, TiW, Ta, TaN, Cr, CrSi, Au, Ag, Cu, Al, and W. The second capacitor electrode 52A may be formed from a conductive material other than those described above. The second capacitor electrode 52A of the present embodiment is formed from a material containing TiN.

The second capacitor electrode 52A includes second electrode wiring 56A, a second capacitor terminal 57A, and a second capacitor ground terminal 58. The second electrode wiring 56A has the form of an elliptical spiral like the second coil wiring 46A shown in FIG. 6. The second electrode wiring 56A is identical in shape to the second coil wiring 46A of the second coil 42A shown in FIG. 6. More specifically, the second electrode wiring 56A has a line width-to-line interval ratio that is the same as that of the second coil wiring 46A.

The second electrode wiring 56A includes a second slit 52As extending from the center of the second electrode wiring 56A toward the outer side of the second electrode wiring 56A. The second electrode wiring 56A has the form of an open loop because of the second slit 52As. The second slit 52As restricts the formation of a current loop in the second electrode wiring 56A.

The second capacitor terminal 57A overlaps the second signal terminal 47A of the second coil 42A shown in FIG. 6. the second capacitor terminal 57A is identical in shape to the second signal terminal 47A in plan view. The second capacitor terminal 57A is located at the inner side of the second electrode wiring 56A and connected to the second electrode wiring 56A. The second capacitor terminal 57A may have any shape. The second capacitor terminal 57A may be omitted.

The second capacitor ground terminal 58 is arranged overlapping the corresponding second ground terminal 48 of the second coil 42A shown in FIG. 6. The second capacitor ground terminal 58 is identical in shape to the second ground terminal 48 in plan view. The second capacitor ground terminal 58 is located between the second capacitor electrode 52A of the capacitor 50A and the second capacitor electrode 52B of the capacitor 50B. The second capacitor ground terminal 58 is electrically connected by connective wiring 58A, which extends toward the center of the second electrode wiring 56A, to each wiring portion of the second electrode wiring 56A.

In plan view, the second capacitor electrode 52B of the capacitor 50B shown in FIG. 8 overlaps the second coil 42B shown in FIG. 6. The second capacitor electrode 52B is formed from a conductive material. Preferably, the second capacitor electrode 52B is formed from a non-magnetic material. The non-magnetic material is one or more of Ti, TiN, TiW, Ta, TaN, Cr, CrSi, Au, Ag, Cu, Al, and W. The second capacitor electrode 52B may be formed from a conductive material other than those described above. The second capacitor electrode 52B of the present embodiment is formed from a material containing TiN.

The second capacitor electrode 52B includes second electrode wiring 56B, a second capacitor terminal 57B, and the second capacitor ground terminal 58. In the same manner as the second coils 42A and 42B shown in FIG. 6, the second capacitor electrodes 52A and 52B share the second capacitor ground terminal 58.

The second electrode wiring 56B has the form of an elliptical spiral like the second coil wiring 46B shown in FIG. 6. The second electrode wiring 56B is identical in shape to the second coil wiring 46B of the second coil 42B shown in FIG. 6. More specifically, the second electrode wiring 56B has a line width-to-line interval ratio that is the same as that of the second coil wiring 46B. The second electrode wiring 56B includes a second slit 52Bs extending from the center of the second electrode wiring 56B toward the outer side of the second electrode wiring 56B. The second electrode wiring 56B has the form of an open loop because of the second slit 52Bs. The second slit 52Bs restricts the formation of a current loop in the second electrode wiring 56B.

The second capacitor terminal 57B is arranged overlapping the second signal terminal 47B of the second coil 42B shown in FIG. 6. The second capacitor terminal 57B is identical in shape to the second signal terminal 47B in plan view. The second capacitor terminal 57B is located at the inner side of the second electrode wiring 56B and connected to the second electrode wiring 56B. The second capacitor terminal 57B may have any shape. The second capacitor terminal 57B may be omitted.

The second capacitor ground terminal 58 is electrically connected by connective wiring 58B, which extends toward the center of the second electrode wiring 56B, to each wiring portion of the second electrode wiring 56B.

The second coil 42A is located farther from the substrate 83 than the first coil 41A in the z-direction. In other words, the second coil 42A is located upward from the first coil 41A. The first coil 41A is located closer to the substrate 83 than the second coil 42A. In the present embodiment, the distance between the first coil 41A and the second coil 42A in the z-direction is greater than the distance between the first coil 41A and the substrate main surface 83s of the substrate 83.

As shown in FIG. 9, the first capacitor electrode 51A and the second capacitor electrode 52A of the capacitor 50A are located between the first coil 41A and the second coil 42A of the transformer 40A. The first capacitor electrode 51A and the second capacitor electrode 52A face each other in the z-direction.

As shown in FIG. 9, the first coil 41A of the transformer 40A is formed on the upper surface of the insulation film 852. The second coil 42A of the transformer 40 is formed in the insulation film 854. Thus, the first coil 41A and the second coil 42A of the transformer 40A are located at opposite sides of the insulation film 853 in the z-direction. The insulation film 853 is formed by the thin films 85A and the interlayer insulation films 85B. Each thin film is, for example, an etching stopper layer. The thin film 85A is formed by a material including SiN, SiC, SiN, or the like. In the present embodiment, the thin film 85A is formed from a material including SiN. Each interlayer insulation film 85B is formed from a material containing SiO₂. As shown in FIG. 9, the interlayer insulation film 85B has a thickness that is greater than that of the thin film 85A. The thickness of the thin film 85A may be 100 nm or greater and less than 1000 nm. The thickness of the interlayer insulation film 85B may be 1000 nm or greater and 3000 nm or less. In the present embodiment, the thickness of the thin film 85A is approximately 300 nm, and the thickness of the interlayer insulation film 85B is approximately 2000 nm.

As shown in FIG. 9, a first insulation film 857 is formed on the upper surface of the first coil 41A. The first insulation film 857 is formed from, for example, a material containing SiN, SiO₂, SiON, SiOC, or the like. The first capacitor electrode 51A of the capacitor 50A is formed on the upper surface of the first insulation film 857. The insulation film 853 covers the upper surface of the first capacitor electrode 51A and the side surfaces of the first coil 41A, the first insulation film 857, and the first capacitor electrode 51A. This embeds the first coil 41A and the first capacitor electrode 51A in the insulation film 853. Further, the first coil 41A and the first capacitor electrode 51A are embedded in the insulation layer 84.

As shown in FIG. 9, the second capacitor electrode 52A of the capacitor 50A is formed on the upper surface of the insulation film 853. A second insulation film 858 is formed on the upper surface of the second capacitor electrode 52A. The second insulation film 858 is formed from, for example, a material containing SiN, SiO₂, SiON, SiOC, or the like. The second coil 42A of the transformer 40A is formed on the upper surface of the second insulation film 858. The insulation film 854 covers the side surfaces of the second capacitor electrode 52A, the second insulation film 858, and the second coil 42A. The uppermost insulation film 85U covers the upper surface of the second coil 42A. This embeds the second coil 42A and the second capacitor electrode 52A in the insulation film 854. Further, the second coil 42A and the second capacitor electrode 52A are embedded in the insulation layer 84.

The distance between the first capacitor electrode 51A and the second capacitor electrode 52A is determined by the thickness of the insulation film 853 between the first capacitor electrode 51A and the second capacitor electrode 52A. The distance is set in accordance with the dielectric breakdown voltage or electric field intensity of the transformer chip 80. When the insulation film 853 includes a plurality of insulation films, the distance between the first capacitor electrode 51A and the second capacitor electrode 52A may be determined by the number of insulation films that are stacked.

As shown in FIG. 9, the first capacitor electrode 51A is electrically connected to the first coil 41A.

The first coil 41A includes the first coil wiring 43A, the first signal terminal 44A, and the first ground terminal 45. The first capacitor electrode 51A includes the first electrode wiring 53A, the first capacitor terminal 54A, and the first capacitor ground terminal 55. The first electrode wiring 53A and the first coil wiring 43A overlap each other in the z-direction. The first capacitor terminal 54A and the first signal terminal 44A overlap each other in the z-direction. The first capacitor ground terminal 55 and the first ground terminal 45 overlap each other in the z-direction.

The first capacitor ground terminal 55 of the first capacitor electrode 51A is connected to the first ground terminal 45 of the first coil 41A. The first insulation film 857 between the first coil 41A and the first capacitor electrode 51A includes a first open portion 857X exposing the first ground terminal 45 of the first coil 41A. The first capacitor ground terminal 55 of the first capacitor electrode 51A includes a part that is connected to the first ground terminal 45 of the first coil 41A in the first open portion 857X. Thus, the first capacitor ground terminal 55 of the first capacitor electrode 51A is electrically connected in the first open portion 857X to the first ground terminal 45 of the first coil 41A.

As shown in FIG. 9, the second capacitor electrode 52A is electrically connected to the second coil 42A.

The second coil 42A includes the second coil wiring 46A, the second signal terminal 47A, and the second ground terminal 48. The second capacitor electrode 52A includes the second electrode wiring 56A, the second capacitor terminal 57A, and the second capacitor ground terminal 58. The second electrode wiring 56A and the second coil wiring 46A overlap each other in the z-direction. The second capacitor terminal 57A and the second signal terminal 47A overlap each other in the z-direction. The second capacitor ground terminal 58 and the second ground terminal 48 overlap each other in the z-direction.

The second capacitor ground terminal 58 of the second capacitor electrode 52A is connected to the second ground terminal 48 of the second coil 42A. The second insulation film 858 between the second capacitor electrode 52A and the second coil 42A includes a second open portion 858X exposing part of the second capacitor ground terminal 58 of the second capacitor electrode 52A. The second ground terminal 48 of the second coil 42A includes a part that is connected to the second capacitor ground terminal 58 of the second capacitor electrode 52A in the second open portion 858X. Thus, the second ground terminal 48 of the second coil 42A is electrically connected in the second open portion 858X to the second capacitor ground terminal 58 of the second capacitor electrode 52A.

As shown in FIG. 4, the first electrode pads 81 and the second electrode pads 82 are each located in the inner region 87 in plan view.

As shown in FIG. 9, the electrode pads 81 and 82 are each formed on the uppermost insulation film 85U. In the present embodiment, the electrode pads 81 and the electrode pads 82 are located farther from the substrate 83 than the second coils 42A and 42B of the transformers 40A and 40B. In other words, the electrode pads 81 and the electrode pads 82 are located upward from the second coils 42A and 42B of the transformers 40A and 40B. In the present embodiment, the distance between the first coil 41A and the second coil 42A is greater than the distance between the second coil 42A and the electrode pads 81 and 82 in the z-direction.

As shown in FIG. 4, in plan view, the first electrode pads 81 are located at positions corresponding to the two transformers 40A and the two transformers 40B in the x-direction and between the transformer 40A and the transformer 40B in the x-direction. The first electrode pads 81 are located closer to the chip side surface 80b than the transformers 40A and 40B in the y-direction. In other words, the first electrode pads 81 are located between the transformers 40A and 40B and the chip side surface 80b in the y-direction. In plan view, the first electrode pads 81 are located closer to the low-voltage leads 92 (refer to FIG. 2) than the transformers 40A and 40B.

In the description hereafter, for the sake of simplicity, the first electrode pads 81 located at positions corresponding to the transformers 40A in the x-direction will be referred to as the first electrode pads 81A. The first electrode pads 81 located at positions corresponding to the transformers 40B in the x-direction will be referred to as the first electrode pads 81B. The first electrode pad 81 located at positions corresponding to between the transformer 40A and the transformer 40B in the x-direction will be referred to as the first electrode pads 81C. The first electrode pads 81A to 81C will be referred to as the first electrode pads 81 when describing common items.

Each first electrode pad 81A overlaps the corresponding transformer 40A as viewed in the y-direction. Each first electrode pad 81B overlaps the corresponding transformer 40B as viewed in the y-direction. Each first electrode pads 81C overlaps a part between the corresponding transformer 40A and the corresponding transformer 40B in the x-direction as viewed in the y-direction. The first electrode pads 81A to 81C are aligned at the same position in the y-direction and separated from one another in the x-direction.

As shown in FIG. 4, in plan view, the second electrode pad 82 are located inside the transformers 40A and 40B and between the transformer 40A and the transformer 40B in the x-direction. The second electrode pads 82 overlap the transformers 40A and 40B as viewed in the x-direction. In the description hereafter, for the sake of simplicity, the second electrode pads 82 in the transformers 40A will be referred to as the second electrode pads 82A, the second electrode pads 82 in the transformer 40B will be referred to as the second electrode pads 82B, and the second electrode pads between the transformer 40A and the transformer 40B will be referred to as the second electrode pads 82C. The second electrode pads 82A to 82C will be referred to as the second electrode pads 82 when describing common items.

Each second electrode pad 82A is located in a space inside the second coil 42A, which has the form of an elliptical spiral, of the corresponding transformer 40A. Each second electrode pad 82B is located in a space inside the second coil 42A, which has the form of an elliptical spiral, of the corresponding transformer 40B. Each second electrode pads 82C is located between the corresponding transformer 40A and the corresponding transformer 40B in the x-direction. The second electrode pads 82A to 82C each include two electrode pads that are adjacent to each other in the x-direction. The second electrode pads 82A to 82C are aligned at the same position in the y-direction and separated from one another in the x-direction.

As shown in FIGS. 4, 5, and 9, each first electrode pad 81A is electrically connected to the first coil 41A of the corresponding transformer 40A. Each first electrode pad 81C is electrically connected to the first coil 41A of the corresponding transformer 40A. As shown in FIGS. 4 and 5, each first electrode pad 81B is electrically connected to the first coil 41B of the corresponding transformer 40B. Each first electrode pad 81C is electrically connected to the first coil 41B of the corresponding transformer 40B. Thus, the first electrode pad 81C is shared by the transformer 40A and the transformer 40B.

As shown in FIGS. 4, 6, and 9, each second electrode pads 82A is electrically connected to the second coil 42A of the corresponding transformer 40A. Each second electrode pad 82C is electrically connected to the second coil 42A of the corresponding transformer 40A. Each second electrode pad 82B shown in FIGS. 4 and 6 is electrically connected to the second coil 42B of the corresponding transformer 40B. Each second electrode pad 82C is electrically connected to the second coil 42B of the corresponding transformer 40B. Thus, the second electrode pad 82C is shared by the transformer 40A and the transformer 40B.

As shown in FIGS. 5 and 6, the transformer chip 80 includes connective wiring that connects the electrode pads 81A to 81C and 82A to 82C to the coils 41A, 41B, 42A, and 42B of the transformers 40A and 40B. In the present embodiment, the connective wiring includes connective wirings 131A, 131B, 131C connecting the first electrode pads 81A to 81C and the first coils 41A and 41B. The connective wirings 131A to 131C are arranged in the inner region 87. The connective wiring 131A to 131C are formed from a material containing Al.

As shown in FIG. 5, each connective wiring 131A connects the corresponding first electrode pad 81A to the first signal terminal 44A of the first coil 41A in the corresponding transformer 40A. Each connective wiring 131B connects the corresponding first electrode pad 81B to the first signal terminal 44B of the first coil 41B in the corresponding transformer 40B. Each connective wiring 131C connects the corresponding first electrode pad 81C to the second end of the first coil 41A in the corresponding transformer 40A and to the second end of the first coil 41B in the corresponding transformer 40B. The connective wiring 131C corresponds to first voltage wiring. The first electrode pads 81C correspond to first ground electrodes. The connective wirings 131A to 131C have the same structure. Thus, the structure of the connective wiring 131A will be described hereafter and the connective wirings 131B and 131C will not be described in detail.

As shown in FIG. 9, the connective wiring 131A includes a first wiring portion 132A, which extends through the insulation layer 84 in the z-direction, and a second wiring portion 133A, which extends in the y-direction.

The first wiring portion 132A, which overlaps the first electrode pad 81A in plan view, is connected to the first electrode pad 81A. The first wiring portion 132A extends from the insulation film 854, which is the first film below the uppermost insulation film 85U, to the insulation film 852, which is the second film above the lowermost insulation film 85L. The first wiring portion 132A includes plate-like wiring parts and a plurality of vias. The wiring parts are located at the same positions as the insulation films 851 and 854 where the coils 41A and 42A are arranged. The vias extend between the two wiring parts in the z-direction, between the upper wiring part and the first electrode pad 81A, and between the lower wiring part and the second wiring portion 133A.

The second wiring portion 133A is located closer to the substrate 83 than the first wiring portion 132A. The second wiring portion 133A is located closer to the substrate 83 than the first coil 41A. In the present embodiment, the second wiring portion 133A is located in the insulation film 851, which is the first film above the lowermost insulation film 85L. The second wiring portion 133A has a first end that is the one of the two ends in the x-direction closer to the chip side surface 80b of the transformer chip 80 and that overlaps the first wiring portion 132A in plan view. The second wiring portion 133A is connected to the first wiring portion 132A. The second wiring portion 133A has a second end that is opposite the first end and overlaps the first coil 41A of the transformer 40A in plan view. More specifically, the second end overlaps the first signal terminal 44A, which is located in the first coil 41A of the transformer 40A, in plan view. The second wiring portion 133A includes vias 134A connecting the second wiring portion 133A and the first signal terminal 44A. The vias 134A are formed from, for example, a material containing W.

As shown in FIG. 9, the connective wiring 131C includes a first wiring portion 132C, which extends through the insulation layer 84 in the z-direction, and a second wiring portion 133C, which extends in the y-direction.

The first wiring portion 132C, which overlaps the first electrode pad 81C in plan view, is connected to the first electrode pad 81C. The first wiring portion 132C extends from the insulation film 854, which is the first film below the uppermost insulation film 85U, to the insulation film 852, which is the second film above the lowermost insulation film 85L. The first wiring portion 132C includes plate-like wiring parts and a plurality of vias. The wiring parts are located at positions where the coils 41A and 42A are arranged in the insulation films 851 and 854. The vias extend between the two wiring parts in the z-direction, between the upper wiring part and the first electrode pad 81C, and between the lower wiring part and the second wiring portion 133C.

The second wiring portion 133C is located closer to the substrate 83 than the first wiring portion 132C. The second wiring portion 133C is located closer to the substrate 83 than the first coil 41A. In the present embodiment, the second wiring portion 133C is located in the insulation film 851, which is the first film above the lowermost insulation film 85L. The second wiring portion 133C has a first end that is the one of the two ends in the x-direction closer to the chip side surface 80b of the transformer chip 80 and overlaps the first wiring portion 132C in plan view. The second wiring portion 133C is connected to the first wiring portion 132C. The second wiring portion 133C has a second end that is opposite the first end and overlaps the first coil 41A of the transformer 40A in plan view. More specifically, the second end overlaps the first ground terminal 45, which is located in the first coil 41A of the transformer 40A, in plan view. The second wiring portion 133C includes vias 134C connecting the second wiring portion 133C and the first signal terminal 44A. The vias 134C are formed from, for example, a material containing W. The second wiring portion 133C of the connective wiring 131C is electrically connected to the substrate 83 by vias 136 extending through the lowermost insulation film 85L. The vias 136 are formed from, for example, a material containing W. The vias 136 may be omitted.

As shown in FIG. 9, the second electrode pad 82A is electrically connected to the second signal terminal 47A of the second coil 42A by vias 135A, which extend through the uppermost insulation film 85U. The second electrode pad 82C is electrically connected to the second ground terminal 48 of the second coil 42A by vias 135C, which extend through the uppermost insulation film 85U. The vias 135A and 135C are formed from, for example, a material containing W.

As shown in FIGS. 4 and 6, in the present embodiment, the transformer chip 80 includes a dummy pattern 120 arranged around the second coils 42A and 42B of the transformers 40A and 40B. The dummy pattern 120 is a dummy coil pattern.

The dummy pattern 120 is arranged in the inner region 87 and includes a first dummy pattern 121, a second dummy pattern 122, and a third dummy pattern 123. The dummy patterns 121 to 123 are formed from a material containing Al.

The first dummy pattern 121 is located in a region between the second coil 42A of the transformer 40A and the second coil 42B of the transformer 40B in the x-direction in plan view. The first dummy pattern 121 differs from the patterns of the second coils 42A and 42B. The first dummy pattern 121 is electrically connected to the second ground terminal 48 of the second coil 42A. The first dummy pattern 121 may be connected to at least one of the second ground terminal 48 of the two second coils 42A. The potential at the first dummy pattern 121 is the same as that at the second coils 42A and 42B. Thus, when the second reference potential at the second coils 42A and 42B varies, the voltage at the first dummy pattern 121 may become higher than that at the first coil 41B in the same manner as the second coil 42B.

Although not shown in the drawings, the first dummy pattern 121 is located at the same position as the second coils 42A and 42B in the z-direction. Thus, the first dummy pattern 121 is located farther from the substrate 83 than the first coils 41A and 41B. The dummy pattern 120 is located around the coil of the one of the transformers 40A and 40B that is closer to the chip main surface 80s of the transformer chip 80.

The voltage at the first dummy pattern 121, which is the same as that at the second coils 42A and 42B, limits voltage drops between the second coils 42A and 42B and the first dummy pattern 121. This limits electric field concentration at the second coils 42A and 42B.

As shown in FIG. 6, the third dummy pattern 123 surrounds the second coils 42A and 42B of the transformers 40A and 40B in plan view. The third dummy pattern 123 is electrically connected to the first dummy pattern 121. Thus, in the same manner as the first dummy pattern 121, as the second reference potential at the second coil 42B changes, the voltage at the third dummy pattern 123 may become higher than that at the first coil 41B.

As shown in FIG. 9, the third dummy pattern 123 is located at the same position as the second coil 42A in the z-direction. Although not shown in the drawings, the third dummy pattern 123 is located at the same position as the second coil 42B in the z-direction. Thus, the third dummy pattern 123 is located farther from the substrate 83 than the first coils 41A and 41B. In this manner, the dummy patterns 121 to 123 are arranged at the same position in the z-direction.

The voltage at the third dummy pattern 123, which is the same as that at the second coils 42A and 42B, limits voltage drops between the second coils 42A and 42B and the third dummy pattern 123. This limits electric field concentration at the second coils 42A and 42B.

As shown in FIG. 6, the second dummy pattern 122 surrounds the third dummy pattern 123 in plan view. The second dummy pattern 122 is independent from the second coils 42A and 42B. That is, the second dummy pattern 122 is not electrically connected to the second coils 42A and 42B.

As shown in FIG. 9, the second dummy pattern 122 is located at the same position as the second coil 42A in the z-direction. Although not shown in the drawings, the second dummy pattern 122 is located at the same position as the second coil 42B in the z-direction. Thus, the second dummy pattern 122 is located farther from the substrate 83 than the first coils 41A and 41B. The second dummy pattern 122 limits increases in the electric field intensity around the second coils 42A and 42B. This limits electric field concentration at the second electrode pads 82A to 82C.

As shown in FIG. 8, in the present embodiment, the transformer chip 80 includes a dummy pattern 125 arranged around the second capacitor electrodes 52A and 52B of the capacitors 50A and 50B. The dummy pattern 125 is structured in the same manner as the dummy pattern 120. The dummy pattern 125 is a dummy electrode pattern. The dummy pattern 125 includes a slit extending from the inner side of the dummy pattern 125 toward the outer side of the dummy pattern 125. The slit restricts the formation of a current loop in the dummy pattern 125.

More specifically, the dummy pattern 125 is arranged in the inner region 87 and includes a first dummy pattern 126, a second dummy pattern 127, and a third dummy pattern 128. The dummy patterns 126 to 128 are formed from, for example, the same material as the second capacitor electrode 52A.

The first dummy pattern 126 is located in a region between the second capacitor electrode 52A of the capacitor 50A and the second capacitor electrode 52B of the capacitor 50B in the x-direction in plan view. The first dummy pattern 126 differs from the patterns of the second capacitor electrodes 52A and 52B. The first dummy pattern 126 is electrically connected to the second capacitor ground terminal 58 of the second capacitor electrode 52A. The first dummy pattern 126 may be connected to at least one of the second capacitor ground terminals 58 of the two second capacitor electrodes 52A. The potential at the first dummy pattern 126 is the same as that at the second capacitor electrodes 52A and 52B. Thus, when the second reference potential at the second capacitor electrodes 52A and 52B varies, the voltage at the first dummy pattern 126 may become higher than that at the first capacitor electrode 51B in the same manner as the second capacitor electrode 52B.

Although not shown in the drawings, the first dummy pattern 126 is located at the same position as the second capacitor electrodes 52A and 52B in the z-direction. Thus, the first dummy pattern 126 is located farther from the substrate 83 than the first capacitor electrodes 51A and 51B. The dummy pattern 125 is located around the coil of the one of the capacitors 50A and 50B that is closer to the chip main surface 80s of the transformer chip 80.

The voltage at the first dummy pattern 126, which is the same as that at the second capacitor electrodes 52A and 52B, limits voltage drops between the second capacitor electrodes 52A and 52B and the first dummy pattern 126. This limits electric field concentration at the second capacitor electrodes 52A and 52B.

As shown in FIG. 8, the third dummy pattern 128 surrounds the second capacitor electrode 52A and 52B of the capacitors 50A and 50B in plan view. The third dummy pattern 128 is electrically connected to the first dummy pattern 126. Thus, in the same manner as the first dummy pattern 126, as the second reference potential at the second capacitor electrode 52B changes, the voltage at the third dummy pattern 128 may become higher than that at the first capacitor electrode 51B.

As shown in FIG. 9, the third dummy pattern 128 is located at the same position as the second capacitor electrode 52A in the z-direction. Although not shown in the drawings, the third dummy pattern 128 is located at the same position as the second capacitor electrode 52B in the z-direction. Thus, the third dummy pattern 128 is located farther from the substrate 83 than the first capacitor electrodes 51A and 51B. In this manner, the dummy patterns 126 to 128 are arranged at the same position in the z-direction.

The voltage at the third dummy pattern 128, which is the same as that at the second capacitor electrodes 52A and 52B, limits voltage drops between the second capacitor electrodes 52A and 52B and the third dummy pattern 128. This limits electric field concentration at the second capacitor electrodes 52A and 52B.

As shown in FIG. 8, the second dummy pattern 127 surrounds the third dummy pattern 128 in plan view. The second dummy pattern 127 is independent from the second capacitor electrodes 52A and 52B. That is, the second dummy pattern 127 is not electrically connected to the second capacitor electrodes 52A and 52B.

As shown in FIG. 9, the second dummy pattern 127 is located at the same position as the second capacitor electrode 52A in the z-direction. Although not shown in the drawings, the second dummy pattern 127 is located at the same position as the second capacitor electrode 52B in the z-direction. Thus, the second dummy pattern 127 is located farther from the substrate 83 than the first capacitor electrodes 51A and 51B. The second dummy pattern 127 limits increases in the electric field intensity around the second capacitor electrodes 52A and 52B. This limits electric field concentration at the second electrode pads 82A to 82C.

As shown in FIG. 9, the transformer chip 80 includes a protective film 150 and a passivation film 160. The protective film 150 is formed on a head surface 84s of the insulation layer 84. The protective film 150 protects the insulation layer 84. The protective film 150 is formed from, for example, a material containing silicon oxide.

The passivation film 160 is a surface protective film of the transformer chip 80. The passivation film 160 is formed from, for example, a material containing silicon nitride. Examples of the material containing silicon nitride include SiN and SiCN. In the present embodiment, the passivation film 160 is formed from a material containing SiN. The passivation film 160 defines the chip main surface 80s of the transformer chip 80.

The first electrode pads 81 and the second electrode pads 82 are covered by the protective film 150 and the passivation film 160. The protective film 150 and the passivation film 160 each include an open portion to partially expose the first electrode pads 81 and the second electrode pads 82. Thus, the first electrode pads 81 each include an exposed surface connected to a wire W2. Further, the second electrode pads 82 each include an exposed surface connected to a wire W3.

As shown in FIGS. 3 and 4, the transformer chip 80 includes a resin layer 180 formed on the passivation film 160. The resin layer 180 is formed from, for example, a material containing polyimide (PI). The resin layer 180 is separated into an inner resin layer 181 and an outer resin layer 182 by an isolation trench 183. As shown in FIG. 4, the isolation trench 183 surrounds the transformers 40A and 40B in plan view. The resin layer 180 includes first resin open portions 184, which expose the first electrode pads 81, and second resin open portions 185, which expose the second electrode pads 82.

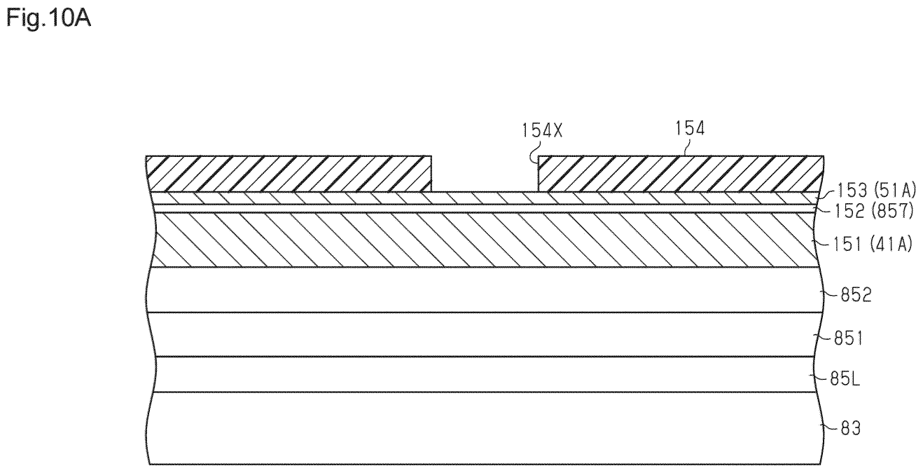

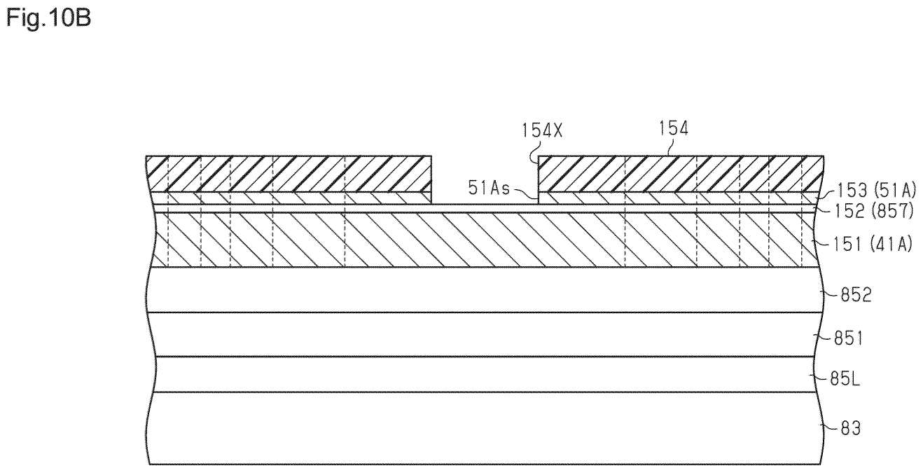

FIGS. 10A and 10B are cross-sectional views illustrating steps for forming the first coil 41A and the first capacitor electrode 51A. FIGS. 10A and 10B illustrate the cross-sectional structures of the first coil 41A shown in FIG. 5 and the first capacitor electrode 51A shown in FIG. 7 as viewed in the x-direction.

As shown in FIG. 10A, a conductive film 151 is formed on the insulation film 852 to form the first coil 41A. An insulation film 152 is formed on the conductive film 151 to form the first insulation film 857, and a conductive film 153 is formed on the insulation film 152 to form the first capacitor electrode 51A. A resist film 154 covers the upper surface of the conductive film 153. The resist film 154 includes an opening 154X at a position corresponding to the slit 51As shown in FIG. 7.

As shown in FIG. 10B, the conductive film 153 exposed from the opening 154X of the resist film 154 is etched to form the slit 51As in the conductive film 153. The etching is stopped by the insulation film 152, which is formed by a material containing SiN.

Then, the resist film 154 is removed. Further, the conductive film 151 and the conductive film 153 are patterned and a resist film (not shown) is formed including an opening corresponding to the section between the patterns of the first coil 41A and the first capacitor electrode 51A. The broken lines in FIG. 10B indicate locations that will become the side surfaces of the first coil 41A, the first insulation film 857, and the first capacitor electrode 51A. The conductive film 151, the insulation film 152, and the conductive film 153 are etched (e.g., dry etched) together from the opening of the resist layer to form the first coil 41A, the first insulation film 857, and the first capacitor electrode 51A.

The steps illustrated above are examples and may be changed. For example, the slit 51As may be formed after the conductive film 151, the insulation film 152, and the conductive film 153 are etched together into the first coil 41A, the first insulation film 857, and the first capacitor electrode 51A.

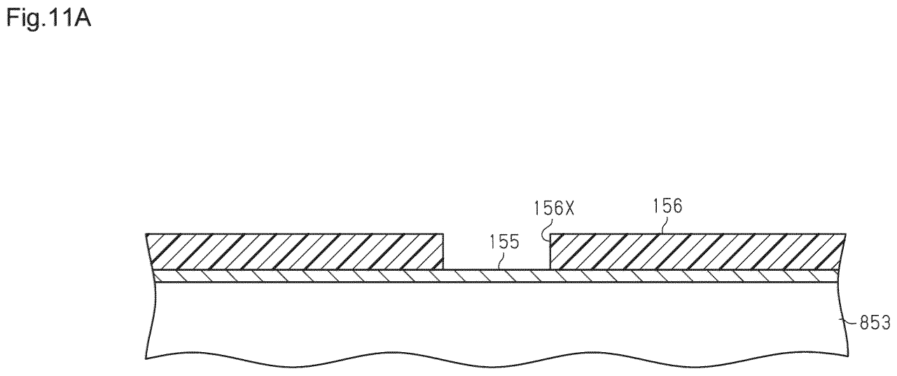

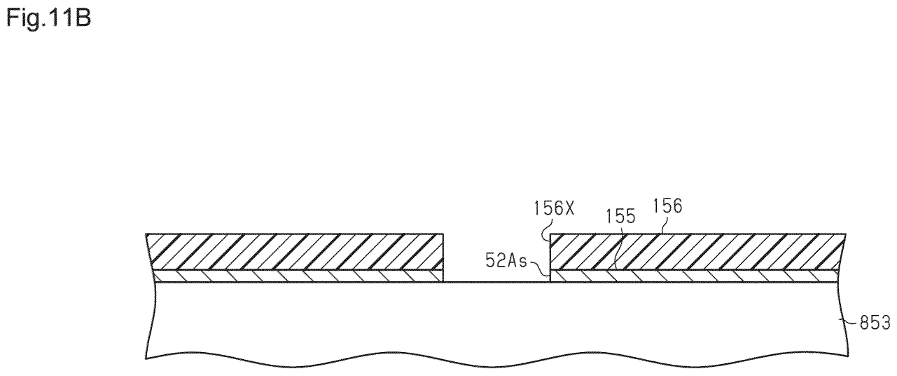

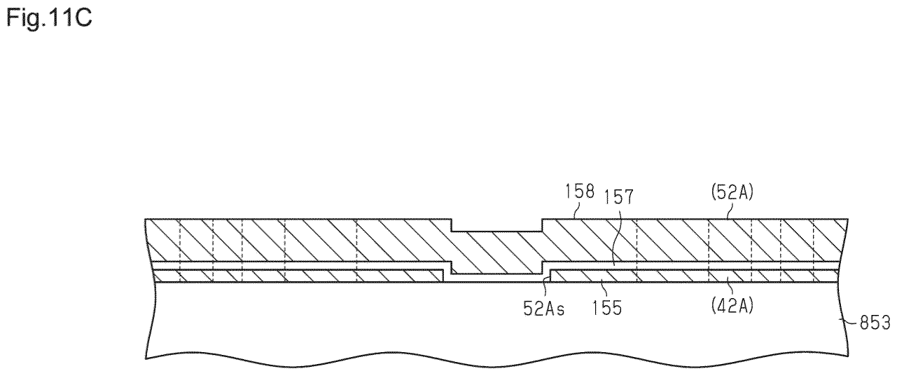

FIGS. 11A to 11C are cross-sectional views illustrating steps for forming the second coil 42A and the second capacitor electrode 52A. FIGS. 11A to 11C illustrate the cross-sectional structures of the second coil 42A shown in FIG. 6 and the second capacitor electrode 52A shown in FIG. 8 as viewed in the x-direction.

As shown in FIG. 11A, a conductive film 155 is formed on the upper surface of the insulation film 853 to form the second capacitor electrode 52A. A resist film 156 is formed on the upper surface of the conductive film 155. The resist film 156 includes an opening 156X at a position corresponding to the slit 51As shown in FIG. 8.

As shown in FIG. 11B, the conductive film 155 exposed from the opening 156X of the resist film 156 is etched to form the slit 52As in the conductive film 155. The etching is stopped by the insulation film 853, which is formed by a material containing SiN.

As shown in FIG. 11C, an insulation film 157, which includes the second insulation film 858 (refer to FIG. 9), is formed on the upper surface of the conductive film 155 and the upper surface of the insulation film 853 that is exposed from the slit 51As of the conductive film 155. Then, a conductive film 158, which forms the second coil 42A, is formed on the upper surface of the insulation film 157. A resist layer (not shown) including an opening, which corresponds to the section between the patterns of the second coil 42A and the second capacitor electrode 52A shown in FIGS. 6 and 8, is formed on the upper surface of the conductive film 158. The broken lines in FIG. 11C indicate locations that will become the side surfaces of the second coil 42A, the second insulation film 858, and the second capacitor electrode 52A. The conductive film 155, the insulation film 157, and the conductive film 158 are dry etched together and removed from the opening of the resist layer to form the second coil 42A, the second insulation film 858, and the second capacitor electrode 52A shown in FIG. 9.

Operation

The operation of the gate driver 10 in accordance with the present embodiment will now be described.

### Comparative Example

A comparative example that is compared with the gate driver 10 of the present embodiment will now be described.

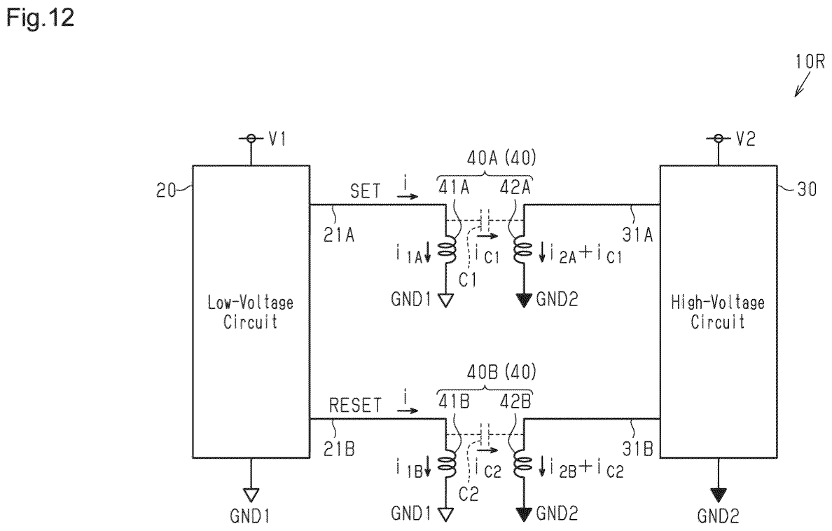

FIG. 12 shows a gate driver 10R of the comparative example. The gate driver 10R of the comparative example does not include the capacitor 50 (capacitors 50A and 50B) shown in FIG. 1. In the gate driver 10R, current i_{C1} flowing through a parasitic capacitor C1 between the first coil 41A and the second coil 42A of the transformer 40A may produce noise in a set signal transmitted from the low-voltage circuit 20 to the high-voltage circuit 30 and cause an erroneous operation. In the same manner, current i_{c2} flowing through a parasitic capacitor C2 between the first coil 41B and the second coil 42B of the transformer 40B may produce noise in a reset signal transmitted from the low-voltage circuit 20 to the high-voltage circuit 30 and cause an erroneous operation.

To prevent erroneous operations caused by such currents i_{C1} and i_{C2}, the high-voltage circuit 30 includes a noise masking circuit. The masking circuit receives, for example, a reset signal (RESET) and then blocks received signals for a certain period. This prevents erroneous operations caused by the parasitic capacitors C1 and C2 when the currents i_{C1} and i_{C2} flow through the second coils 42A and 42B.

The capacitance of the parasitic capacitors C1 and C2 may differ between gate drivers 10R or differ in accordance with the operational state. That is, the capacitance of the parasitic capacitors C1 and C2 is unstable. This may change the position where noise is superposed on the set signal and reset signal. Accordingly, a long masking period should be set for the high-voltage circuit 30 in accordance with where noise may be produced. Since signals cannot be transmitted during the masking period, high-speed signal transmission from the low-voltage circuit 20 to the high-voltage circuit 30 will be impeded. The same problem will occur if signals are transmitted from the high-voltage circuit 30 to the low-voltage circuit 20. Thus, the low-voltage circuit 20 will also require a masking circuit in the same manner as the high-voltage circuit 30.

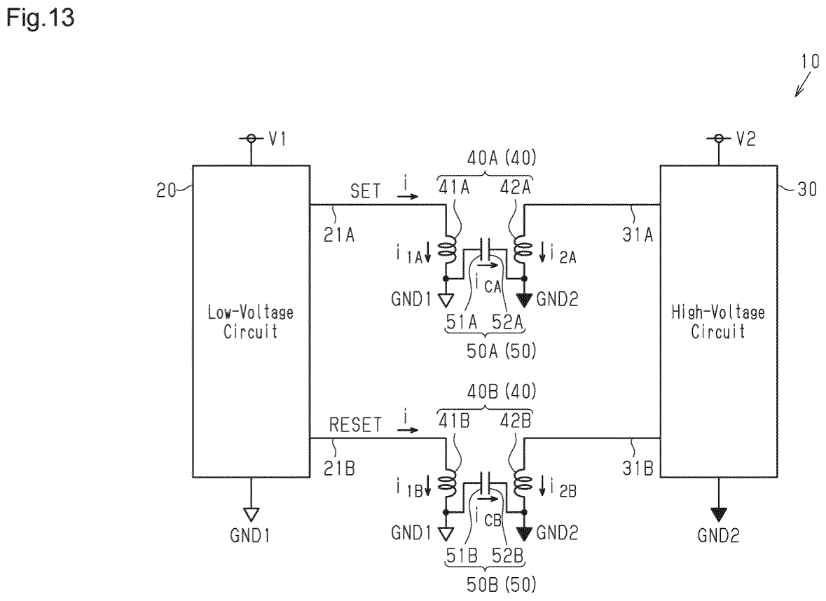

FIG. 13 shows the operation of the gate driver 10 in accordance with the present embodiment.

As described above, the gate driver 10 of the present embodiment includes the transformer 40A, which includes the first coil 41A and the second coil 42A, and the transformer 40B, which includes the first coil 41B and the second coil 42B. Further, the gate driver 10 includes the capacitor 50A, which is connected between the ground terminal of the first coil 41A and the ground terminal of the second coil 42A, and the capacitor 50B, which is connected between the ground terminal of the first coil 41B and the ground terminal of the second coil 42B.

The first capacitor electrode 51A of the capacitor 50A is electrically connected to the first coil 41A and has the same potential as that at the first coil 41A. The second capacitor electrode 52A of the capacitor 50A is electrically connected to the second coil 42A and has the same potential as that at the second coil 42A. The first capacitor electrode 51B of the capacitor 50B is electrically connected to the first coil 41B and has the same potential as that at the first coil 41B. The second capacitor electrode 52B of the capacitor 50B is electrically connected to the second coil 42B and has the same potential as that at the second coil 42B.

The transformer 40A and the transformer 40B are used to, for example, transmit a set signal (SET) and a reset signal (RESET) from the low-voltage circuit 20 to the high-voltage circuit 30.

In this case, in response to a set signal output from the low-voltage circuit 20, current i_{1A} flows through the first coil 41A of the transformer 40A. Current i_{2A} flows through the second coil 42A that is magnetically coupled to the first coil 41A. The high-voltage circuit 30 generates a pulse signal from current i_{2A}, that is, receives the set signal.

Current i_{CA} resulting from the set signal flows between the first capacitor electrode 51A of the capacitor 50A and the second capacitor electrode 52A. The current i_{CA} flows from the second capacitor electrode 52A to the ground terminal of the second coil 42A, or ground GND2. This reduces the effect of the current i_{CA}, which flows through the capacitor 50A, on the current i_{2A}, which flows through the second coil 42A of the transformer 40A. Thus, the effect on the transmission of a signal is reduced between the low-voltage circuit 20 and the high-voltage circuit 30.

In the same manner, in response to a reset signal output from the low-voltage circuit 20, current i_{1B} flows through the first coil 41B of the transformer 40B. Current i_{2B} flows through the second coil 42B that is magnetically coupled to the first coil 41B. The high-voltage circuit 30 generates a pulse signal from current i_{2B}, that is, receives the reset signal.

Current i_{CB} resulting from the reset signal flows between the first capacitor electrode 51B of the capacitor 50B and the second capacitor electrode 52B. The current i_{CB} flows from the second capacitor electrode 52B to the ground terminal of the second coil 42B, or ground GND2. This reduces the effect of the current i_{CB}, which flows through the capacitor 50B, on current i_{2B}, which flows through the second coil 42B of the transformer 40B. Thus, the effect on the transmission of a signal is reduced between the low-voltage circuit 20 and the high-voltage circuit 30.

Current i_{CA} flows with a phase lag from the current i of the set signal that is in accordance with the impedance of the transformer 40A and the capacitance of the capacitor 50A. In the same manner, current i_{CB} flows with a phase lag from the current i of the reset signal that is in accordance with the impedance of the transformer 40B and the capacitance of the capacitor 50B. Thus, even if currents i_{CA} and i_{CB} affect the signals received by the high-voltage circuit 30, the masking period is set in accordance with the timing of the currents i_{CA} and i_{CB}. The length of the masking period will be shorter than that required for the parasitic capacitor C1. This will reduce the effect on high-speed signal transmission.

Advantages

The gate driver 10 of the present embodiment has the advantages described below.

(1-1) The transformer chip 80 includes the transformer 40A, the transformer 40B, the capacitor 50A, and the capacitor 50B. The capacitor 50A includes the first capacitor electrode 51A and the second capacitor electrode 52A located between the first coil 41A and the second coil 42A of the transformer 40A. The capacitor 50B includes the first capacitor electrode 51B and the second capacitor electrode 52B located between the first coil 41B and the second coil 42B of the transformer 40B. The first capacitor electrodes 51A and 51B are connected to the first ground terminal 45 of the first coils 41A and 41B. The second capacitor electrodes 52A and 52B are connected to the second ground terminal 48 of the second coils 42A and 42B.

With this configuration, the transformer 40A and the transformer 40B are used to transmit a set signal (SET) and a reset signal (RESET) from the low-voltage circuit 20 to the high-voltage circuit 30. In response to the set signal, current i_{CA}, which flows through the capacitor 50A, flows from the second capacitor electrode 52A to the ground terminal of the second coil 42A, or ground GND2. This reduces the effect of the current i_{CA}, which flows through the capacitor 50A, on the current i_{2A}, which flows through the second coil 42A of the transformer 40A. Thus, the effect on the transmission of a signal is reduced between the low-voltage circuit 20 and the high-voltage circuit 30.

Further, in response to the reset signal, current i_{CB}, which flows through the capacitor 50B, flows from the second capacitor electrode 52B to the ground terminal of the second coil 42B, or ground GND2. This reduces the effect of the current i_{CB}, which flows through the capacitor 50B, on current i_{2B}, which flows through the second coil 42B of the transformer 40B. Thus, the effect on the transmission of a signal is reduced between the low-voltage circuit 20 and the high-voltage circuit 30.

(1-2) Current i_{CA}, which flows through the capacitor 50A, flows with a phase lag from the current i of the set signal that is in accordance with the impedance of the transformer 40A and the capacitance of the capacitor 50A. Current i_{CB}, which flows through the capacitor 50B, flows with a phase lag from the current i of the set signal that is in accordance with the impedance of the transformer 40B and the capacitance of the capacitor 50B. Thus, even if currents i_{CA} and i_{CB} affect the signal received by the high-voltage circuit 30, the masking period is set in accordance with the phase of the currents i_{CA} and i_{CB}. This facilitates the design of the high-voltage circuit 30. The length of the masking period is shorter than that required for the parasitic capacitor C1. This will reduce the effect on high-speed signal transmission.

(1-3) In plan view, the dummy pattern 120 is located around the second coils 42A and 42B. This reduces electric field concentration at the second coils 42A and 42B.

(1-4) In plan view, the dummy pattern 125 is located around the second capacitor electrodes 52A and 52B. This reduces electric field concentration at the second capacitor electrodes 52A and 52B.

(1-5) The gate driver 10 includes the low-voltage circuit 20, the high-voltage circuit 30, and the transformer chip 80. The low-voltage circuit 20 and the high-voltage circuit 30 are connected by the transformer chip 80 and are configured to transmit signals through the transformer chip 80. The transformer chip 80 includes the transformer 40A, the transformer 40B, the capacitor 50A, and the capacitor 50B. The capacitor 50A includes the first capacitor electrode 51A and the second capacitor electrode 52A located between the first coil 41A and the second coil 42A of the transformer 40A. The capacitor 50B includes the first capacitor electrode 51B and the second capacitor electrode 52B located between the first coil 41B and the second coil 42B of the transformer 40B. The first capacitor electrodes 51A and 51B are connected to the first ground terminal 45 of the first coils 41A and 41B. The second capacitor electrodes 52A and 52B are connected to the second ground terminal 48 of the second coils 42A and 42B. This configuration has the same advantage as advantage (1-1), which is described above. Thus, the effect on transmitted signals is reduced in the gate driver 10.

(1-6) The gate driver 10 that includes the transformer 40 and the capacitor 50 may be a low-voltage circuit chip that includes the low-voltage circuit 20, the transformer 40, and the capacitor 50. It may also be a high-voltage circuit chip that includes the high-voltage circuit 30 and the transformer 40 and the capacitor 50. However, in these configurations, when the circuit configuration of the low-voltage circuit 20 or the high-voltage circuit 30 is changed, the entire chip will also have to be changed. This will increase costs since different types of gate drivers will be manufactured.

In this respect, in the present embodiment, the transformer 40 and the capacitor 50 are included in the transformer chip 80 that is independent from the low-voltage circuit chip 60 and the high-voltage circuit chip 70. In other words, a chip is used exclusively as the transformer 40. Thus, the transformer chip 80 can be shared by the low-voltage circuit 20 and the high-voltage circuit 30 that differ from each other. This reduces costs as with when manufacturing different types of the gate driver 10 because of one of the low-voltage circuit 20 and the high-voltage circuit 30 being different.

(1-7) The first coil 41A and the first capacitor electrode 51A of the present embodiment are located at opposite sides of the first insulation film 857. The first coil 41A and the first capacitor electrode 51A are formed from a conductive metal. The first insulation film 857 is formed from, for example, SiN. That is, the first coil 41A, the first insulation film 857, and the first capacitor electrode 51A may form a metal-insulator-metal (MIM) structure. In the same manner, the second coil 42A, the second capacitor electrode 52A, and the second insulation film 858 may form a metal-insulator-metal (MIM) structure. This facilitates the formation of a MIM structure capacitor or the like on the transformer chip 80.

(1-8) The first capacitor electrode 51A and the second capacitor electrode 52A are formed from a non-magnetic material. When the non-magnetic material is, for example, TiN, CrSi, or the like, a resistor element can be easily formed with the non-magnetic material on the transformer chip 80.

### Modified Examples

The embodiment described above exemplifies, without any intention to limit, applicable forms of an insulating module and a gate driver according to this disclosure. The insulating module and gate driver in accordance with this disclosure may be modified from the embodiment described above. For example, the configuration in the above embodiment may be replaced, changed, or omitted in part or include an additional element. The modified examples described below may be combined as long as there is no technical contradiction. In the modified examples described hereafter, same reference characters are given to those components that are the same as the corresponding components of the above embodiment. Such components will not be described in detail.

The shape of the capacitor 50 in the above embodiment may be changed.

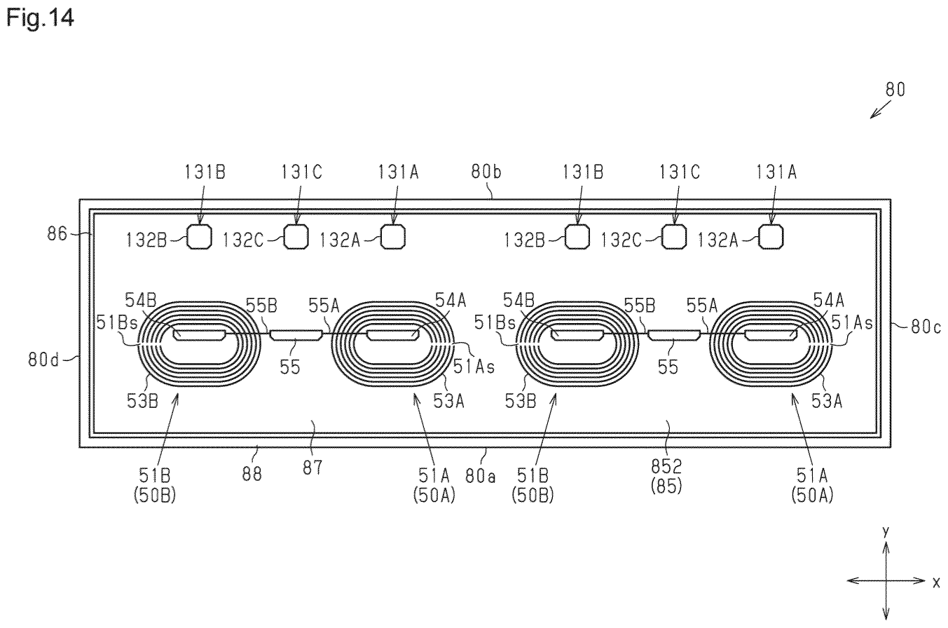

FIG. 14 shows the first capacitor electrodes 51A and 51B of the modified example. The first capacitor electrode 51A has the form of an elliptical loop so as to overlap the first coil wiring 43A of the first coil 41A shown in FIG. 5. The first electrode wiring 53A of the first capacitor electrode 51A in the modified example includes loops of wirings arranged from an inner end 43i of the first coil wiring 43A shown in FIG. 5 to an outer end 43o of the first coil wiring 43A. The slit 51As extends outward from the center of the first capacitor electrode 51A. The first capacitor electrode 51A has the form of an open loop because of the slit 51As.

The first capacitor electrode 51B has the form of an elliptical loop so as to overlap the first coil wiring 43B of the first coil 41B shown in FIG. 5. The first capacitor electrode 51B of the modified example includes loops of wirings arranged from the inner end 43i of the first coil wiring 43B shown in FIG. 5 to the outer end 43o of the first coil wiring 43B. The first slit 51Bs extends outward from the center of the first capacitor electrode 51B. The first capacitor electrode 51B has the form of an open loop because of the first slit 51Bs.

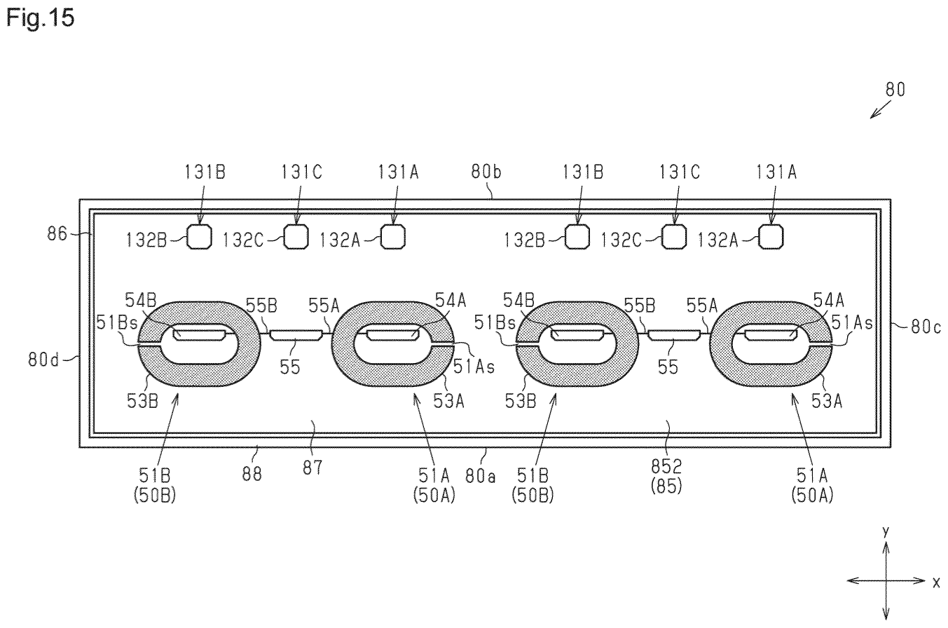

FIG. 15 shows the first capacitor electrodes 51A and 51B of the modified example. The first capacitor electrode 51A has the form of an elliptical loop so as to overlap the first coil wiring 43A of the first coil 41A shown in FIG. 5. The first electrode wiring 53A of the first capacitor electrode 51A in the modified example has the form of a plate extending continuously from the inner end 43i of the first coil wiring 43A shown in FIG. 5 to the outer end 43o of the first coil wiring 43A. The first slit 51As extends outward from the center of the first capacitor electrode 51A. The first capacitor electrode 51A has the form of an open loop because of the first slit 51As.

The first capacitor electrode 51B has the form of an elliptical loop so as to overlap the first coil wiring 43B of the first coil 41B shown in FIG. 5. The first electrode wiring 53B of the first capacitor electrode 51B in the modified example has the form of a plate extending continuously from the inner end 43i of the first coil wiring 43B shown in FIG. 5 to the outer end 43o of the first coil wiring 43B. The first slit 51Bs extends outward from the center of the first capacitor electrode 51B. The first capacitor electrode 51B has the form of an open loop because of the first slit 51Bs.

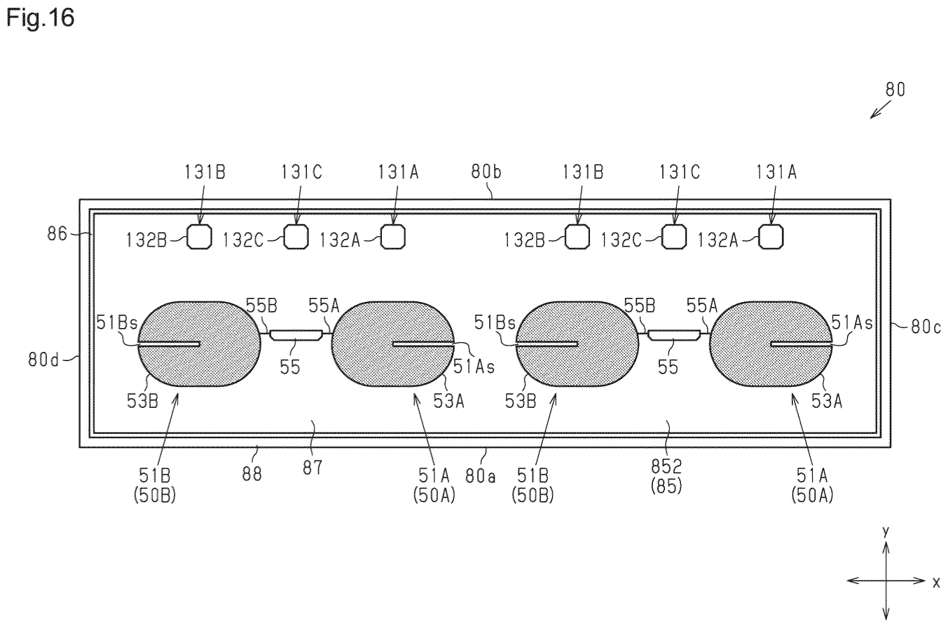

FIG. 16 shows the first capacitor electrodes 51A and 51B of the modified example. The first capacitor electrode 51A has the form of an elliptical plate so as to overlap the first coil wiring 43A and the first signal terminal 44A of the first coil 41A shown in FIG. 5. The first electrode wiring 53A of the first capacitor electrode 51A in the modified example has the form of a plate extending continuously from the center of the first coil 41A shown in FIG. 5 to the outer end 43o of the first coil wiring 43A. Thus, the first electrode wiring 53A of the modified example includes the first signal terminal 44A shown in FIG. 5. The first slit 51As extends outward from the center of the first capacitor electrode 51A.

The first capacitor electrode 51B has the form of an elliptical plate so as to overlap the first coil wiring 43B and the first signal terminal 44B of the first coil 41B shown in FIG. 5. The first capacitor electrode 51B of the modified example has the form of a plate extending continuously from the center of the first coil 41B shown in FIG. 5 to the outer end 43o of the first coil wiring 43B. Thus, the first electrode wiring 53B of the modified example includes the first signal terminal 44B shown in FIG. 5. The first slit 51Bs extends outward from the center of the first capacitor electrode 51B.

In the above embodiment, the z-direction cross sections of the first coil 41A, the second coil 42A, the first capacitor electrode 51A, the second capacitor electrode 52A, and the dummy patterns 120 and 125 may be changed.

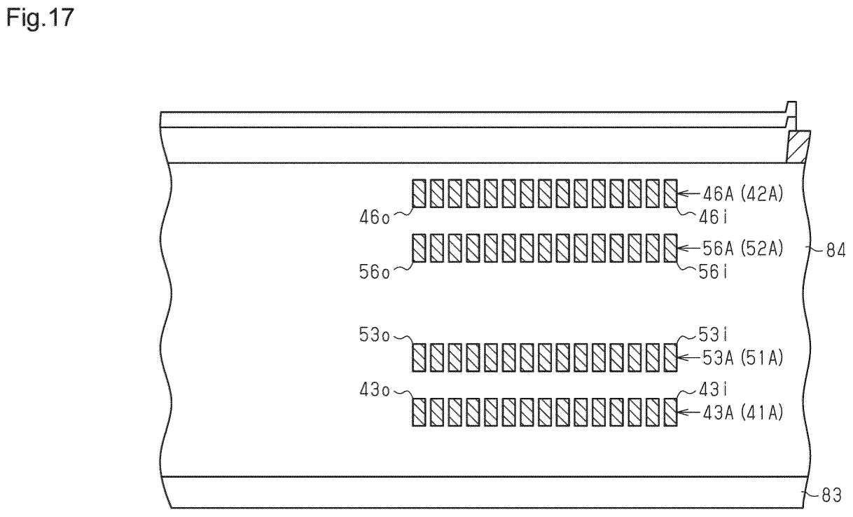

FIGS. 17 to 25 show cross sections of part of the transformer chip 80 taken in the z-direction.

As shown in FIG. 17, the dummy pattern 120 corresponding to the second coil 42A and the dummy pattern 125 (refer to FIG. 9) corresponding to the second capacitor electrode 52A may be omitted.

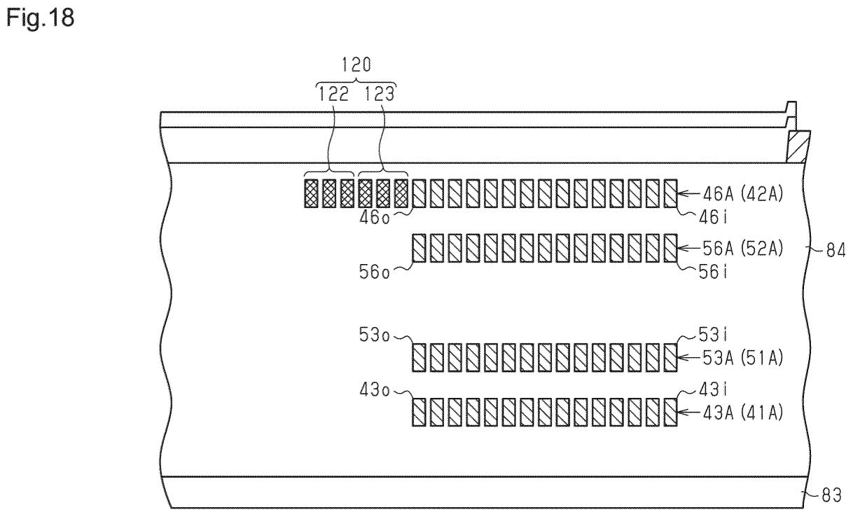

As shown in FIG. 18, the dummy pattern 125 (refer to FIG. 9) corresponding to the second capacitor electrode 52A may be omitted leaving only the dummy pattern 120 corresponding to the second coil wiring 46A of the second coil 42A. The dummy pattern 120 corresponding to the second coil wiring 46A of the second coil 42A may be omitted leaving only the dummy pattern 125 (refer to FIG. 9) corresponding to the second capacitor electrode 52A.

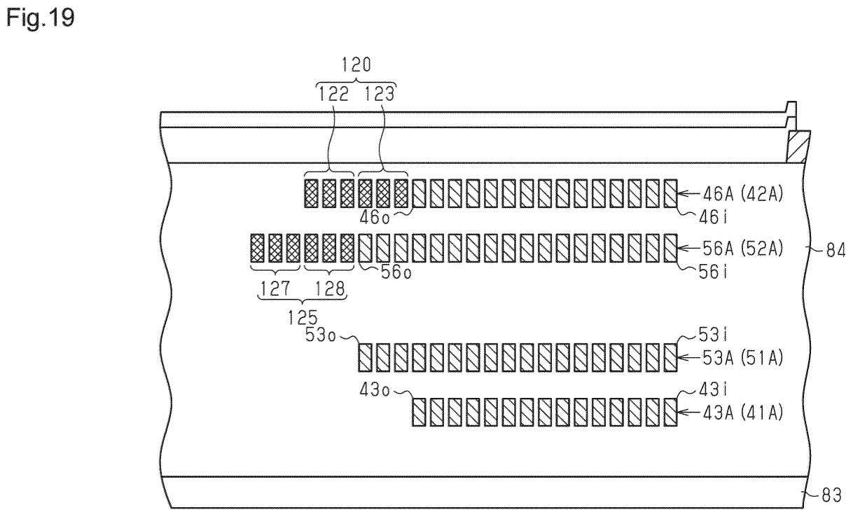

As shown in FIG. 19, an outer end 53o of the first electrode wiring 53A of the first capacitor electrode 51A is located outward from the outer end 43o of the first coil wiring 43A of the first coil 41A. An inner end 53i of the first electrode wiring 53A of the first capacitor electrode 51A is located at the same position as the inner end 43i of the first coil wiring 43A of the first coil 41A. An outer end 56o of the second electrode wiring 56A of the second capacitor electrode 52A is located outward from an outer end 46o of the second coil wiring 46A of the second coil 42A. An inner end 56i of the second electrode wiring 56A of the second capacitor electrode 52A is located at the same position as an inner end 46i of the second coil wiring 46A of the second coil 42A.

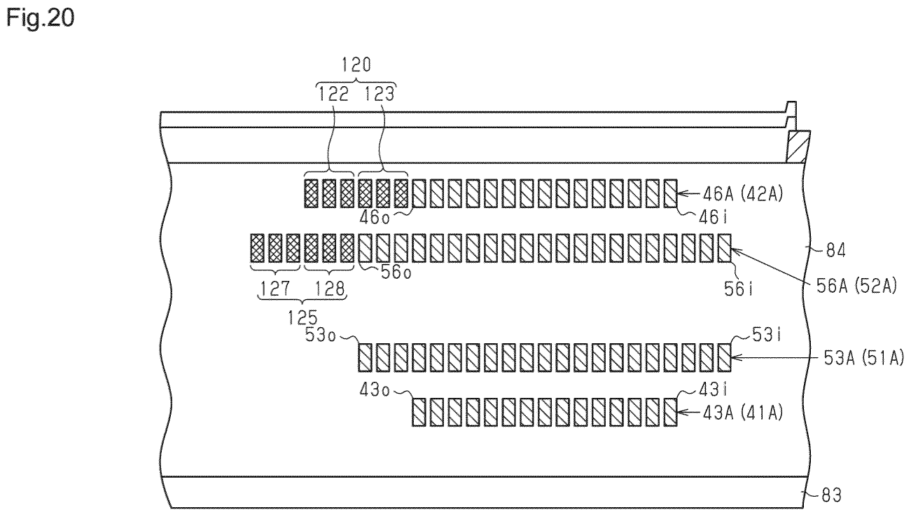

As shown in FIG. 20, the outer end 53o of the first electrode wiring 53A of the first capacitor electrode 51A is located outward from the outer end 43o of the first coil wiring 43A of the first coil 41A. The inner end 53i of the first electrode wiring 53A of the first capacitor electrode 51A is located inward from the inner end 43i of the first coil wiring 43A of the first coil 41A. The outer end 56o of the second electrode wiring 56A of the second capacitor electrode 52A is located outward from the outer end 46o of the second coil wiring 46A of the second coil 42A. The inner end 56i of the second electrode wiring 56A of the second capacitor electrode 52A is located inward from the inner end 46i of the second coil wiring 46A of the second coil 42A.

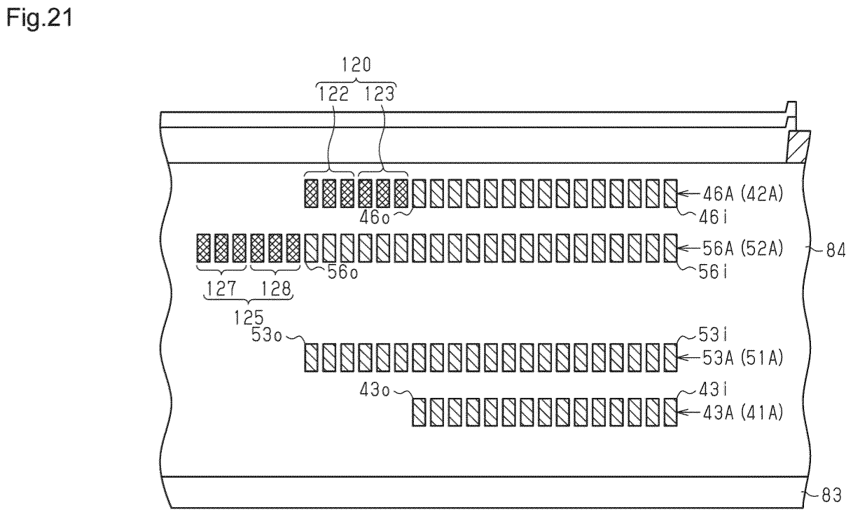

As shown in FIG. 21, the first electrode wiring 53A of the first capacitor electrode 51A and the second electrode wiring 56A of the second capacitor electrode 52A overlap the second coil wiring 46A of the second coil 42A and the dummy pattern 120. Thus, the outer end 53o of the first electrode wiring 53A of the first capacitor electrode 51A is located at the same position as the outer end of the dummy pattern 120, which is located at the outer side of the second coil wiring 46A of the second coil 42A. In the same manner, the outer end 56o of the second electrode wiring 56A of the second capacitor electrode 52A is located at the same position as the outer end of the dummy pattern 120, which is located at the outer side of the second coil wiring 46A of the second coil 42A. The inner end 53i of the first electrode wiring 53A of the first capacitor electrode 51A is located at the same position as the inner end 43i of the first coil wiring 43A of the first coil 41A. The inner end 56i of the second electrode wiring 56A of the second capacitor electrode 52A is located at the same position as the inner end 46i of the second coil wiring 46A of the second coil 42A.

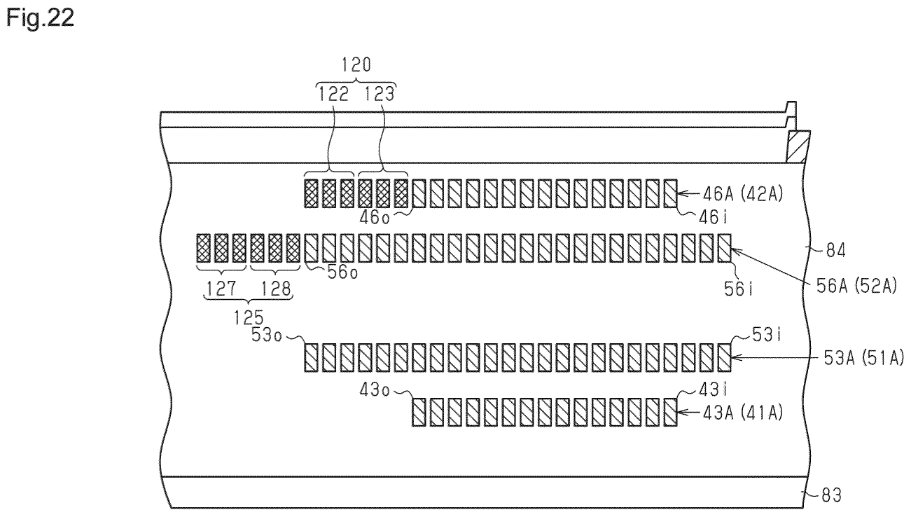

As shown in FIG. 22, the first electrode wiring 53A of the first capacitor electrode 51A and the second electrode wiring 56A of the second capacitor electrode 52A overlap the second coil wiring 46A of the second coil 42A and the dummy pattern 120. Thus, the outer end 53o of the first electrode wiring 53A of the first capacitor electrode 51A is located at the same position as the outer end of the dummy pattern 120, which is located at the outer side of the second coil wiring 46A of the second coil 42A. In the same manner, the outer end 56o of the second electrode wiring 56A of the second capacitor electrode 52A is located at the same position as the outer end of the dummy pattern 120, which is located at the outer side of the second coil wiring 46A of the second coil 42A. The inner end 53i of the first electrode wiring 53A of the first capacitor electrode 51A is located inward from the inner end 43i of the first coil wiring 43A of the first coil 41A. The inner end 56i of the second electrode wiring 56A of the second capacitor electrode 52A is located inward from the inner end 46i of the second coil wiring 46A of the second coil 42A.

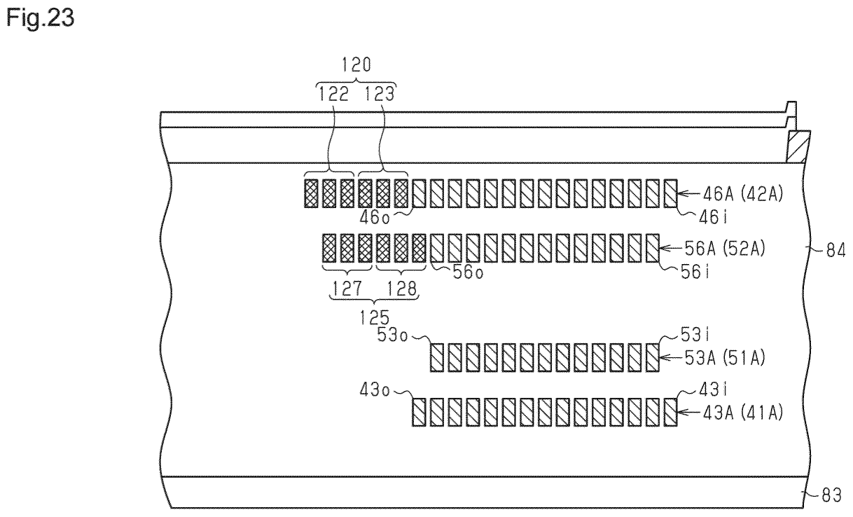

As shown in FIG. 23, the outer end 53o of the first electrode wiring 53A of the first capacitor electrode 51A is located inward from the outer end 43o of the first coil wiring 43A of the first coil 41A. The inner end 53i of the first electrode wiring 53A of the first capacitor electrode 51A is located outward from the inner end 43i of the first coil wiring 43A of the first coil 41A. The outer end 56o of the second electrode wiring 56A of the second capacitor electrode 52A is located inward from the outer end 46o of the second coil wiring 46A of the second coil 42A. The inner end 56i of the second electrode wiring 56A of the second capacitor electrode 52A is located outward from the inner end 46i of the second coil wiring 46A of the second coil 42A.

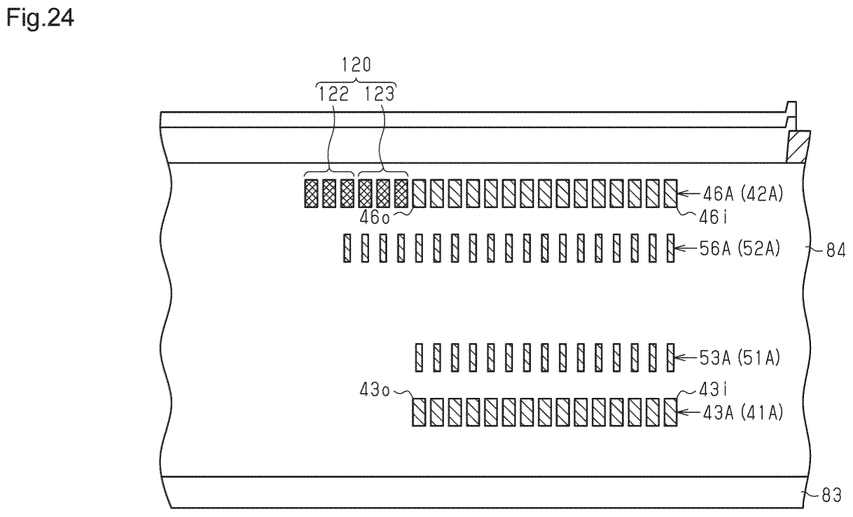

As shown in FIG. 24, the first electrode wiring 53A of the first capacitor electrode 51A has a line width that is less than that of the first coil wiring 43A of the first coil 41A. Thus, the first electrode wiring 53A has a line width-to-line interval ratio that is smaller than that of the first coil wiring 43A. The second electrode wiring 56A of the second capacitor electrode 52A has a line width that is less than that of the second coil wiring 46A of the second coil 42A. Thus, the second electrode wiring 56A has a line width-to-line interval ratio that is smaller than that of the second coil wiring 46A.

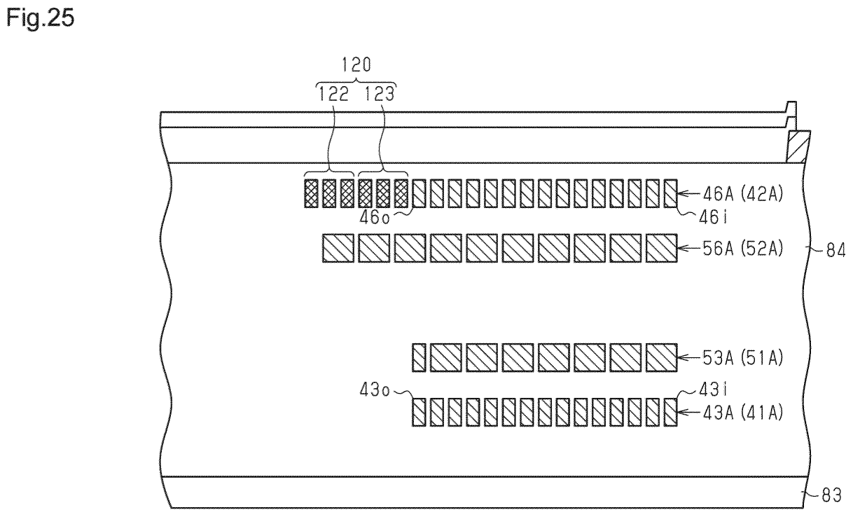

As shown in FIG. 25, the first electrode wiring 53A of the first capacitor electrode 51A has a line width that is greater than that of the first coil wiring 43A of the first coil 41A. Thus, the first electrode wiring 53A has a line width-to-line interval ratio that is larger than that of the first coil wiring 43A. The second electrode wiring 56A of the second capacitor electrode 52A has a line width that is greater than that of the second coil wiring 46A of the second coil 42A. Thus, the second electrode wiring 56A has a line width-to-line interval ratio that is larger than that of the second coil wiring 46A.

In this manner, the first coil wiring 43A (first coil 41A) and the second coil wiring 46A (second coil 42A) may have any shape. Further, the first electrode wiring 53A (first capacitor electrode 51A) and the second electrode wiring 56A (second capacitor electrode 52A) may have any shape. For example, in the z-direction, the first coil wiring 43A and the second coil wiring 46A may have a thickness that differs from that of the first electrode wiring 53A and the second electrode wiring 56A.

In the above embodiment, the passivation film 160 does not have to be formed from a material containing silicon nitride as long as it can protect the insulation layer 84.

In the above embodiment, the transformers 40A and 40B and the capacitors 50A and 50B may be laid out in any manner. In one example, the transformer 40A, the transformer 40A, the transformer 40B, and the transformer 40B are arranged in order from the chip side surface 80c toward the chip side surface 80d of the transformer chip 80. The capacitors 50A and 50B are arranged in correspondence with the transformers 40A and 40B.

In the above embodiment, the first dummy pattern 121 of the dummy pattern 120 is electrically connected to the second coil 42B. This, however, is not a limitation. For example, the first dummy pattern 121 may be independent from the second coils 42A and 42B. Thus, the first dummy pattern 121 does not have to be electrically connected to the second coils 42A and 42B. Further, in the above embodiment, the third dummy pattern 123 is electrically connected to the first dummy pattern 121. This, however, is not a limitation. For example, the third dummy pattern 123 does not have to be electrically connected to the first dummy pattern 121.

In the above embodiment, the first dummy pattern 126 of the dummy pattern 125 is electrically connected to the first capacitor electrode 51A. This, however, is not a limitation. For example, the first dummy pattern 126 may be independent from the first capacitor electrodes 51A and 51B. That is, the first dummy pattern 126 does not have to be electrically connected to the first capacitor electrodes 51A and 51B. Further, in the above embodiment, the third dummy pattern 128 is electrically connected to the first dummy pattern 126. This, however, is not a limitation. For example, the third dummy pattern 128 does not have to be electrically connected to the first dummy pattern 126.

In the above embodiment, the dummy pattern 120, which corresponds to the second coils 42A and 42B, may have any configuration. For example, one or two of the first dummy pattern 121, the second dummy pattern 122, and the third dummy pattern 123 may be omitted from the dummy pattern 120. Further, the dummy pattern 120 may be omitted from the transformer chip 80.

In the above embodiment, the dummy pattern 125, which corresponds to the second capacitor electrodes 52A and 52B, may have any configuration. For example, one or two of the first dummy pattern 126, the second dummy pattern 127, and the third dummy pattern 128 may be omitted from the dummy pattern 125. Further, the dummy pattern 125 may be omitted from the transformer chip 80.

In the above embodiment, the low-voltage circuit 20 and the transformer 40 are formed on separate chips. This, however, is not a limitation. The transformer 40 and the low-voltage circuit 20 may be mounted on the same chip. For example, the low-voltage circuit 20 may be formed on the substrate 83 of the transformer chip 80. The transformer chip 80 is covered by the mold resin 110.

In the above embodiment, the high-voltage circuit 30 and the transformer 40 are formed on separate chips. This, however, is not a limitation. The transformer 40 and the high-voltage circuit 30 may be mounted on the same chip. For example, the high-voltage circuit 30 may be formed on the substrate 83 of the transformer chip 80. In this case, the transformer chip 80 is mounted on the high-voltage die pad 101. The transformer chip 80 is covered by the mold resin 110.

In the above embodiment, the gate driver 10 may include an insulating module that accommodates the transformer 40 in a single package. The insulating module includes the transformer chip 80 and the mold resin 110, which encapsulates the transformer chip 80. The insulating module may further include a die pad, on which the transformer chip 80 is mounted, leads, and wires connecting the leads and the transformer chip 80. The mold resin 110 encapsulates at least the transformer chip 80, the die pad, and the wires. The leads are connected to both the low-voltage circuit 20 and the high-voltage circuit 30.

In the above embodiment, the gate driver 10 may include a low-voltage circuit unit that accommodates the low-voltage circuit 20 and the transformer 40 in a single package. The low-voltage circuit unit may include the low-voltage circuit chip 60, the transformer chip 80, and the mold resin 110 encapsulating the low-voltage circuit chip 60 and the transformer chip 80. The low-voltage circuit unit may further include a die pad, first leads, first wires connecting the first leads and the low-voltage circuit chip 60, second leads, and second wires connecting the second leads and the transformer chip 80. The mold resin 110 encapsulates the low-voltage circuit chip 60, the transformer chip 80, the die pad, and the wires. The first leads are, for example, electrically connectable to the ECU 503, and the second leads are electrically connectable to the high-voltage circuit 30.

In the above embodiment, the gate driver 10 may include a high-voltage circuit unit that accommodates the high-voltage circuit 30 and the transformer 40 in a single package. The high-voltage circuit unit may include the high-voltage circuit chip 70, the transformer chip 80, and the mold resin 110 encapsulating both the high-voltage circuit chip 70 and the transformer chip 80. The high-voltage circuit may further include a die pad, first leads, first wires connecting the first leads and the high-voltage circuit chip 70, second leads, and second wires connecting the second leads and the transformer chip 80. The mold resin 110 encapsulates at least the high-voltage circuit chip 70, the transformer chip 80, the die pad, and the wires. The first leads are, for example, electrically connectable to the source of the switching element 501, and the second leads are electrically connectable to the low-voltage circuit 20.

The above embodiment may be configured to transmit signals from the high-voltage circuit 30 via the transformer 40 and the capacitor 50 to the low-voltage circuit 20. Further, the low-voltage circuit 20 and the high-voltage circuit 30 may be configured to transmit signals bidirectionally with the transformer 40 and the capacitor 50.

In the above embodiment, the first coil 41A and the second coil 42A may differ in the number of windings from the first coil 41B and the second coil 42B. Further, the first coil 41A and the second coil 42A may differ in winding direction from the first coil 41B and the second coil 42B.

In the above embodiment, the slits 51As and 51Bs shown in FIG. 7 may be located at any position. In FIG. 7, the slits 51As and 51Bs extend in the x-direction but may extend in the y-direction. Further, the two slits 51As and Bs may extend in the same direction, for example, toward the chip side surface 80c. In the same manner, the slits 52As and 52Bs shown in FIG. 8 may be located at any position. Further, the slit 51As, shown in FIG. 7, and the slit 52As, shown in FIG. 8, may extend in different directions. In the same manner, the slit 51Bs, shown in FIG. 7, and the slit 52Bs, shown in FIG. 8, may extend in different directions.

In this specification, the word “on” includes the meaning of “above” in addition to the meaning of “on” unless otherwise described in the context. Accordingly, the phrase of “A formed on B” means that A contacts B and is directly arranged on B, and may also mean, as a modified example, that A is arranged above B without contacting B. Thus, the word “on” will also allow for a structure in which another member is formed between A and B.

The z-direction referred to in this specification does not necessarily have to be the vertical direction and does not necessarily have to completely coincide with the vertical direction. Accordingly, in the structures of the present disclosure, up and down in the z-direction as referred to in this specification is not limited to up and down in the vertical direction. For example, the x-direction may be the vertical direction. Alternatively, the y-direction may be the vertical direction.

In this specification, “at least one of A and B” should be understood to mean “only A, only B, or both A and B.”

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. An insulating transformer, comprising:
an insulation layer;
a transformer embedded in the insulation layer and including a first coil and a second coil, the first coil including a first signal terminal and a first ground terminal and being configured to allow for application of a low voltage to the first signal terminal, and the second coil being separated from the first coil in a thickness direction of the insulation layer, including a second signal terminal and a second ground terminal, and being configured to allow for application of a high voltage to the second signal terminal;
a capacitor including a first capacitor electrode and a second capacitor electrode, the first capacitor electrode being located between the first coil and the second coil and connected to the first ground terminal of the first coil, and the second capacitor electrode being located between the first capacitor electrode and the second coil and connected to the second ground terminal of the second coil;
a first insulation film located between the first coil and the first capacitor electrode; and
a second insulation film located between the second coil and the second capacitor electrode.

2. The insulating transformer according to claim 1, wherein:
the first insulation film includes a first open portion exposing part of the first ground terminal of the first coil;
the first capacitor electrode is connected to the first ground terminal of the first coil exposed by the first open portion;
the second insulation film includes a second open portion exposing part of the second capacitor electrode; and
the second ground terminal of the second coil includes a portion in the second open portion, and the second capacitor electrode is connected to the second ground terminal in the second open portion.

3. The insulating transformer according to claim 1, wherein the first coil and the second coil are formed from a material containing aluminum.

4. The insulating transformer according to claim 1, wherein at least one of the first capacitor electrode and the second capacitor electrode is formed from a material including a non-magnetic material.

5. The insulating transformer according to claim 1, wherein:
the first capacitor electrode has the form of an open loop with a first slit extending from a center of the first coil toward an outer side of the first coil as viewed in the thickness direction; and
the second capacitor electrode has the form of an open loop with a second slit extending from a center of the second coil toward an outer side of the second coil as viewed in the thickness direction.

6. The insulating transformer according to claim 1, wherein:
the first coil includes first coil wiring having a spiral form, the first ground terminal connected to one end of the first coil wiring, and the first signal terminal connected to another end of the first coil wiring; and
the second coil includes second coil wiring having a spiral form, the second ground terminal connected to one end of the second coil wiring, and the second signal terminal connected to another end of the second coil wiring.

7. The insulating transformer according to claim 6, wherein:
the first capacitor electrode includes first electrode wiring overlapping the first coil wiring as viewed in the thickness direction, a first capacitor end overlapping the first signal terminal as viewed in the thickness direction, and a first capacitor ground terminal overlapping the first ground terminal as viewed in the thickness direction; and
the second capacitor electrode includes second electrode wiring overlapping the second coil wiring as viewed in the thickness direction, a second capacitor end overlapping the second signal terminal as viewed in the thickness direction, and a second capacitor ground terminal overlapping the second ground terminal as viewed in the thickness direction.

8. The insulating transformer according to claim 7, wherein:
the first electrode wiring has a line width-to-line interval ratio that is the same as that of the first coil wiring; and
the second electrode wiring has a line width-to-line interval ratio that is the same as that of the second coil wiring.

9. The insulating transformer according to claim 7, wherein an outer end of the second electrode wiring is located outward from an outer end of the second coil wiring as viewed in the thickness direction.

10. The insulating transformer according to claim 7, wherein an outer end of the second electrode wiring and an outer end of the second coil wiring are located at the same position as viewed in the thickness direction.

11. The insulating transformer according to claim 9, wherein an inner end of the second electrode wiring and an inner end of the second coil wiring are located at the same position as viewed in the thickness direction.

12. The insulating transformer according to claim 9, wherein an inner end of the second electrode wiring is located inward from an inner end of the second coil wiring as viewed in the thickness direction.

13. The insulating transformer according to claim 7, wherein an outer end of the first electrode wiring is located outward from an outer end of the first coil wiring as viewed in the thickness direction.

14. The insulating transformer according to claim 7, wherein an outer end of the second electrode wiring and an outer end of the second coil wiring are located at the same position in the thickness direction.

15. The insulating transformer according to claim 13, wherein an inner end of the first electrode wiring and an inner end of the first coil wiring are located at the same position as viewed in the thickness direction.

16. The insulating transformer according to claim 13, wherein an inner end of the first electrode wiring is located inward from an inner end of the first coil wiring as viewed in the thickness direction.

17. The insulating transformer according to claim 1, further comprising:
a chip main surface and a chip back surface that are located at opposite sides in the thickness direction, wherein the second coil is located at the side of the chip main surface; and
a dummy coil pattern arranged around the second coil and connected to the second coil.
